(19) United States
(12) Patent Application Publication
(10) Pub. No.: US 2026/0017905 A1
(43) Pub. Date: Jan. 15, 2026

(54) METHODS, STORAGE MEDIA, AND SYSTEMS FOR COMBINING DISPARATE 3D MODELS OF A COMMON BUILDING OBJECT

(71) Applicant: Hover Inc., San Francisco, CA (US)

(72) Inventors: Matthew Thomas, San Francisco, CA (US); Jacob Burkhart, Pacifica, CA (US); Yevheniia Dzitsiuk, San Francisco, CA (US); Jeffrey Sommers, Los Alto Hills, CA (US); Harsh Barbhaiya, San Francisco, CA (US); Manish Upendran, San Francisco, CA (US); Kerry Gould, San Francisco, CA (US); Anna Marie Clifton, San Francisco, CA (US)

(73) Assignee: Hover Inc., San Francisco, CA (US)

(21) Appl. No.: 18/880,830

(22) PCT Filed: Jun. 29, 2023
(86) PCT No.: PCT/US2023/069392

§ 371 Date: Jan. 2, 2025

Related U.S. Application Data
(60) Provisional application No. 63/358,716, filed on Jul. 6, 2022.
(60) Provisional application No. 63/510,633, filed on Jun. 28, 2023.

(51) Int. Cl. G06T 19/20; G06F 30/13; G06T 17/00

(52) U.S. Cl. CPC G06T 19/20; G06F 30/13; G06T 17/00; G06T 2210/04; G06T 2219/2004

(57) ABSTRACT

Methods, storage media, and systems for combining disparate 3d models of a common building object are disclosed. Exemplary implementations may: receive a first plurality of images; generate a first 3d model based on the first plurality of images; receive a second plurality of images; generate a second 3d model based on the second plurality of images; and align, in a common 3d coordinate system, the first 3d model with the second 3d model.

### CROSS-REFERENCE TO RELATED APPLICATIONS

The present application claims priority to U.S. Provisional Application No. to 63/510,633 filed Jun. 27, 2023 entitled “METHODS, STORAGE MEDIA, AND SYSTEMS FOR COMBINING DISPARATE 3D MODELS OF ACOMMON BUILDING OBJECT,” and U.S. Provisional Application No. 63/358,716 filed on Jul. 6, 2022 entitled “METHODS, STORAGE MEDIA, AND SYSTEMS FOR AUGMENTING DATA OR MODELS”, which are hereby incorporated by reference in its entirety.

The present application is related to PCT Application No. PCT/US22/36416 and U.S. Provisional Application No. 63/219,804 filed on Jul. 8, 2021 entitled “INTERIORS”.

### BACKGROUND

### Field of the Invention

The present disclosure relates to methods, storage media, and systems for augmenting two-dimensional and/or three-dimensional data or models.

### Description of Related Art

Data, such as two-dimensional (2D) data (e.g., visual data), three-dimensional (3D) data (e.g., depth data), or both, can be captured. Models, such as 2D models (e.g., digital representations in 2D space), 3D models (e.g., digital representations in 3D space), or both, can be generated. Different data capture techniques and reconstruction techniques can result in varying degrees of representation of the data, and different modeling techniques can result in varying degrees of robustness in the models. In embodiments where the models are generated based on the data, these variances can propagate and result in inconsistencies among the models, even when the models are based on the same underlying object.

### BRIEF SUMMARY

Aligning one model with another model can address issues related to different capture techniques, reconstruction techniques, and modeling techniques. Aligning one model with another model can be used to revise, refine, or complete, the models. In some embodiments, one model can be leveraged to improve another model, such as, for example, by imputing or combining the data of one to another.

In some aspects, a common coordinate system between models is used. A common coordinate system may be derived from a coordinate system of either model, from dominant axes of either model (such as a Manhattan axis system), from common attributes of the models (such as common features or geometries), or other methods as described herein.

One aspect of the present disclosure relates to a method for combining disparate 3d models of a common building object. The method may include receiving a first plurality of images. The method may include generating a first 3d model based on the first plurality of images. The first 3d model may be an interior model of the building object. The method may include receiving a second plurality of images. The method may include generating a second 3d model based on the second plurality of images. The second 3d model may be an exterior model of the building object. The method may include aligning, in a common 3d coordinate system, the first 3d model with the second 3d model.

Another aspect of the present disclosure relates to a non-transient computer-readable storage medium having instructions embodied thereon, the instructions being executable by one or more processors to perform a method for combining disparate 3d models of a common building object. The method may include receiving a first plurality of images. The method may include generating a first 3d model based on the first plurality of images. The first 3d model may be an interior model of the building object. The method may include receiving a second plurality of images. The method may include generating a second 3d model based on the second plurality of images. The second 3d model may be an exterior model of the building object. The method may include aligning, in a common 3d coordinate system, the first 3d model with the second 3d model.

Yet another aspect of the present disclosure relates to a system configured for combining disparate 3d models of a common building object. The system may include one or more hardware processors configured with machine-readable instructions. The processor(s) may be configured to receive a first plurality of images. The processor(s) may be configured to generate a first 3d model based on the first plurality of images. The first 3d model may be an interior model of the building object. The processor(s) may be configured to receive a second plurality of images. The processor(s) may be configured to generate a second 3d model based on the second plurality of images. The second 3d model may be an exterior model of the building object. The processor(s) may be configured to align, in a common 3d coordinate system, the first 3d model with the second 3d model.

These and other features, and characteristics of the present technology, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention. As used in the specification and in the claims, the singular form of ‘a’, ‘an’, and ‘the’ include plural referents unless the context clearly dictates otherwise.

### BRIEF DESCRIPTION OF THE DRAWINGS

FIG. 1 illustrates 3D data of an interior environment, according to some embodiments.

FIGS. 2A-2D illustrate 3D data of an interior environment, according to some embodiments.

FIG. 3A illustrates 3D data of an interior environment, according to some embodiments.

FIG. 3B illustrates visual data of a portion of the interior environment of FIG. 3A, according to some embodiments.

FIG. 4A illustrates a top down view of a capture (e.g., scan) subprocess of a 3D reconstruction process of an exterior, according to some embodiments.

FIGS. 4B-4E illustrate images captured by a capture device at poses illustrated in FIG. 4A, according to some embodiments.

FIG. 4F illustrates a front-left view of a model, according to some embodiments.

FIG. 4G illustrates a back-right view of a model, according to some embodiments.

FIG. 5A illustrates interior 3D data augmented with an exterior 3D model, according to some embodiments.

FIG. 5B illustrates a magnified view of a portion of FIG. 5A, according to some embodiments.

FIG. 6A illustrates a top-down view of a floorplan representation generated based on 3D data, according to some embodiments.

FIG. 6B illustrates a top-down view of a floorplan representation and augmented 3D data, according to some embodiments.

FIG. 6C illustrates a perspective view of a floorplan representation and augmented 3D data, according to some embodiments.

FIG. 7A illustrates a floorplan with a capture path, according to some embodiments.

FIG. 7B illustrates a floorplan with a capture path, according to some embodiments.

FIG. 8 illustrates a block diagram of a computer system that may be used to implement the techniques described herein, according to some embodiments.

FIG. 9 illustrates a system configured for augmenting 3D models, according to some embodiments.

FIG. 10 illustrates a method for augmenting 3D models, according to some embodiments.

FIG. 11 illustrates a system configured for combining disparate 3d models of a common building object, according to some embodiments.

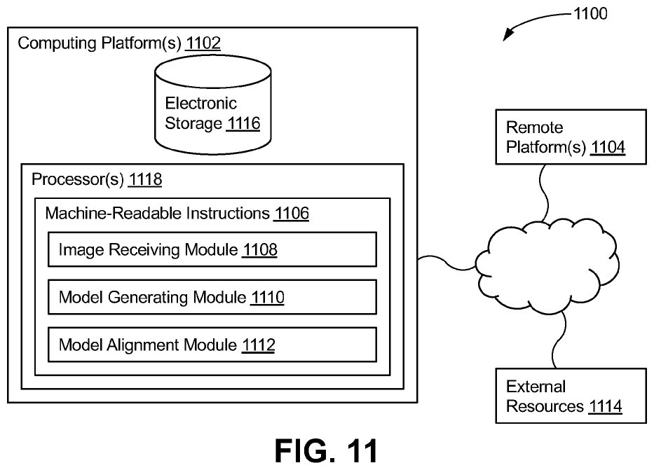

FIG. 12 illustrates a method for combining disparate 3d models of a common building object, according to some embodiments.

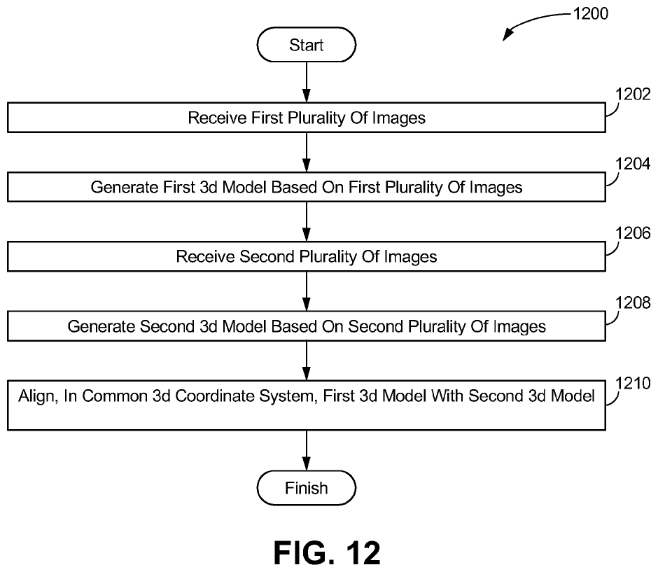

FIG. 13 illustrates a system configured for combining disparate 3d models of a common building object, according to some embodiments.

FIG. 14 illustrates a method for combining disparate 3d models of a common building object, according to some embodiments.

In the following description, for the purposes of explanation, numerous specific details are set forth in order to provide a thorough understanding of the present disclosure. It will be appreciated, however, that the present disclosure may be practiced without these specific details. In other instances, well-known structures and devices are shown in block diagram form in order to avoid unnecessarily obscuring the present disclosure. Like reference numbers and designations in the various drawing indicate like elements.

### DETAILED DESCRIPTION

A 3D reconstruction process can use 3D capturing or scanning techniques implemented on a 3D scanner to capture or receive 3D data (sometimes referred to as “images” generally, including depth data) of an environment that is used to generate a 2D or 3D model that can be displayed. The 2D or the 3D model can be a polygon-based model (e.g., a mesh model), a primitive-based model, and the like. In some embodiments, the 3D reconstruction process can use 2D capturing or scanning techniques implemented on a 2D scanner to capture or receive 2D data (sometimes referred to as “images” generally, including visual data) of an environment that is used to generate a 2D or 3D model that can be displayed. The 2D or 3D model can be a polygon-based model (e.g., a mesh model), a primitive-based model, and the like. The 3D reconstruction process can include one or more subprocesses such as, for example, a capture subprocess, a reconstruction subprocess, a display subprocess, and the like.

Examples of 3D capturing or scanning techniques include time-of-flight, triangulation, structured light, modulated light, stereoscopic, photometric, photogrammetry, and the like. Examples of 3D data include depth data such as, for example, 3D point clouds, 3D line clouds, 3D meshes, 3D points, and the like. Examples of 3D models include mesh models (e.g., polygon models), surface models, wire-frame models, computer-aided-design (CAD) models, and the like.

Examples of 2D capturing or scanning techniques include global shutter capture, rolling shutter capture, panoramic capture, wide-angle capture (e.g., 180 degree camera capture, 360 degree camera capture, etc.), image capture, video capture, and the like. Examples of 2D data include visual data such as, for example, image data, video data, and the like.

In some embodiments, the 3D reconstruction process can capture the 3D data and the 2D data synchronously or asynchronously. In some embodiments, the 3D reconstruction process can capture data (e.g., the 3D data or the 2D data) at a fixed interval or as a function of movement of a scanner (e.g., the 3D scanner or the 2D scanner). The 3D reconstruction process can capture data based on translation thresholds, rotation thresholds, or both. For example, the 3D reconstruction process can capture data if the scanner translates more than a translation threshold, rotates more than a rotation threshold, or both.

The 2D data, the 3D data, or both, can be captured by a smartphone, a tablet computer, an augmented reality headset, a virtual reality headset, a drone, an aerial platform, and the like, or a combination thereof. The 2D data, the 3D data, or both, can include a building object, for example an interior of the building object, an exterior of the building object, or both.

In some embodiments, the 2D data can be used to augment the 3D data. For example, the 3D data can be textured based on the 2D data.

A model (e.g., the 3D model or the 2D model) can be a floorplan representation of the environment. The floorplan can be an envelope representation including an outline of the environment, or a detailed representation including an outline of the environment and elements such as portals (e.g., doors, windows, space-to-space openings, and the like), interior walls, fixed furniture/appliances, and the like. The floorplan representation can include measurements, labels for the different spaces and elements within the environment, and the like. Examples of labels for the different spaces include entryway, reception, foyer, living room, family room, kitchen, bedroom, bathroom, closet, hallway, corridor, staircase, balcony, terrace, and the like. Examples of labels for the different elements include refrigerator, washer/dryer, dishwasher, range, microwave, range hood, wall oven, cooktop, toilet, sink, bath, exhaust fans, countertops, cabinets, and the like.

Limitations of 3D capturing or scanning techniques can cause lines that are straight in the environment to appear distorted in the 3D data. As a distance between the 3D scanner and a surface in the environment increases, the likelihood of distortion artifacts, such as wavy, broken, or disjointed geometry, in the 3D data increases which can lead to an inaccurate 3D model. The presence and magnitude of the distortion artifacts can depend on the 3D capturing or scanning techniques implemented on the 3D scanner.

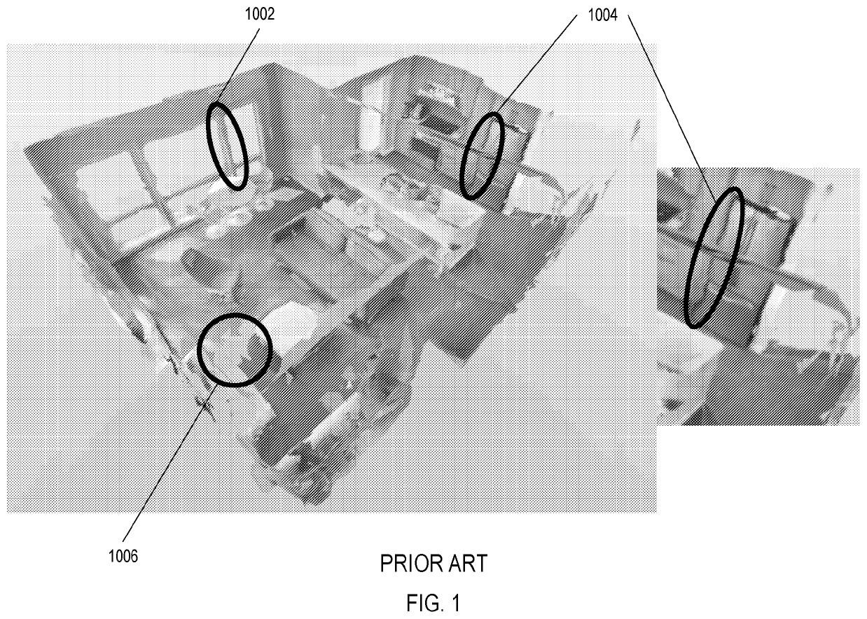

FIG. 1 illustrates 3D data of an interior environment, according to some embodiments. Window frame artifact 1002 and fridge artifact 1004 are examples of wavy, broken, or disjointed geometry due to sensor drift, false positives in feature matching, or noisy scene information.

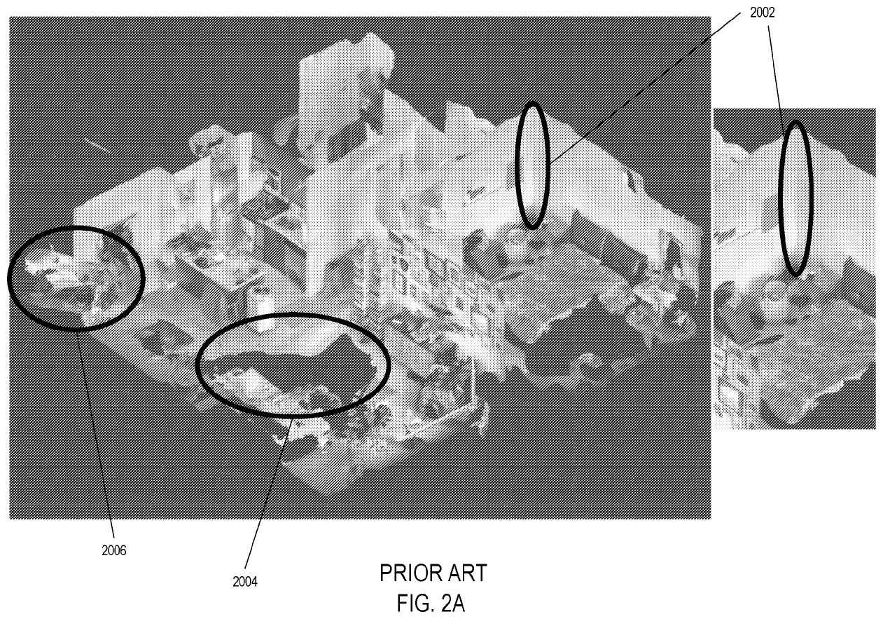

FIGS. 2A-2D illustrate 3D data of an interior environment, according to some embodiments. Wall artifact 2002 and wall artifact 2014 are examples of wavy, broken, or disjointed geometry due to sensor drift, false positives in feature matching, or noisy scene information.

The likelihood of wavy, broken, or disjointed geometry in the 3D data can be mitigated by decreasing the distance between the 3D scanner and a surface in the environment. Decreasing the distance between the 3D scanner and a surface in the environment may be difficult in certain circumstances. For example, in an environment with a high vaulted ceiling, it may not be possible to decrease the distance between the 3D scanner and the ceiling as the 3D scanner may not be able to get close to the ceiling.

The environment can include potentially problematic surfaces, such as reflective surfaces, dark surfaces, and clear or transparent surfaces, which can lead to artifacts, such as duplicative elements, missing data referred to as holes, or additional data, in the 3D data. Examples of reflective surfaces include mirrors, and the like. Examples of dark surfaces include television screens, dark tabletops or countertops, and the like. Examples of clear surfaces include glass, clear plastics, glass tabletops or countertops, and the like.

Referring briefly to FIGS. 2A-2D, first mirror 2008 and second mirror 2012 are examples of reflective surfaces that lead to duplicative elements in the 3D data referred to as first mirror artifact 2006 and second mirror artifact 2010, respectively.

Manually adjusting settings of the 3D scanner to take into account the potentially problematic surfaces before or during 3D data capture, manually adjusting the 3D scanner's pose (e.g., position and orientation) relative to the potentially problematic surfaces during 3D data capture, manually identifying the potentially problematic surfaces in the environment or in the 3D data, or manually identifying the artifacts in the 3D data caused by the potentially problematic surfaces can be an indirect, cumbersome, or resource intensive processes.

3D capturing or scanning techniques that do not observe all portions of all surfaces of an environment can lead to artifacts, such as missing data referred to as holes, in the 3D data at the surfaces or portions thereof that are not observed.

Referring briefly to FIG. 1, hole 1006 is an example of an area where there is no 3D data from capturing or scanning. Referring briefly to FIGS. 2A-2D, hole 2004 is an example of an area where there is no 3D data from capturing or scanning.

Known hole filling techniques may work well for holes that are mostly flat but may not work as well for holes that have an irregular shape or curvature. Regardless of situations in which they may or may not work well, known hole filling techniques can be resource intensive or computationally expensive.

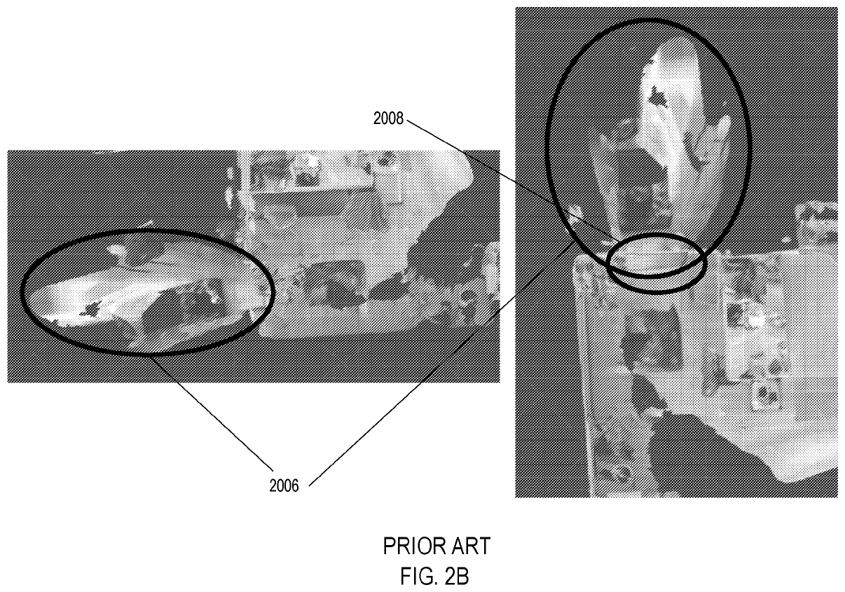

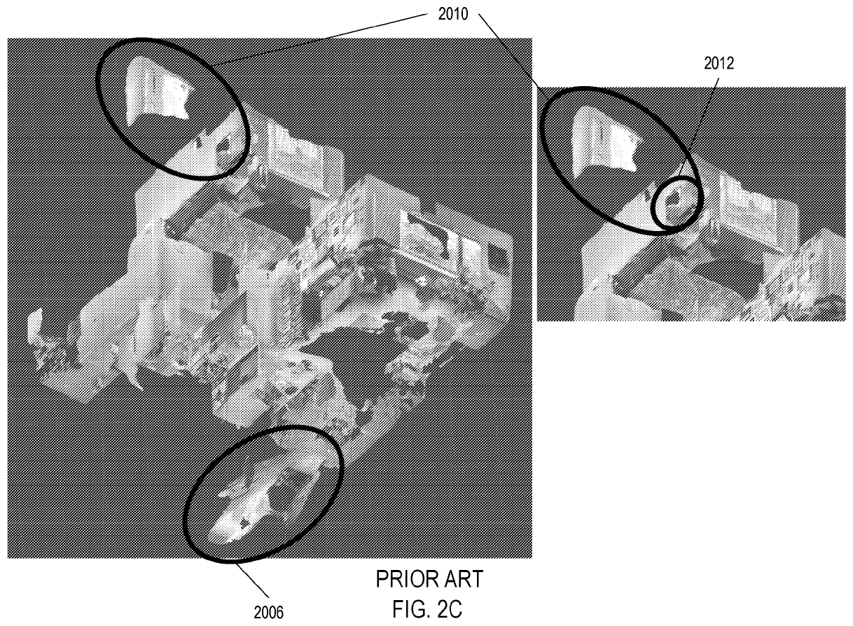

FIG. 3A illustrates 3D data of an interior environment, according to some embodiments. FIG. 3B illustrates visual data of a portion of the interior environment of FIG. 3A, according to some embodiments. Visual data in FIG. 3B indicates that 3004 should be depicted as a solid wall, however, the reconstructed 3D data in FIG. 3A indicates that 3002, which is the same portion as 3004 of FIG. 3B, is a void. 3D reconstruction of the interior environment based on the 3D data of the interior environment illustrated in FIG. 3A would result in a model including a void, whereas 3D reconstruction of the interior environment based on the visual data in FIG. 3B would result in a wall. This is an example of different inputs producing different outputs.

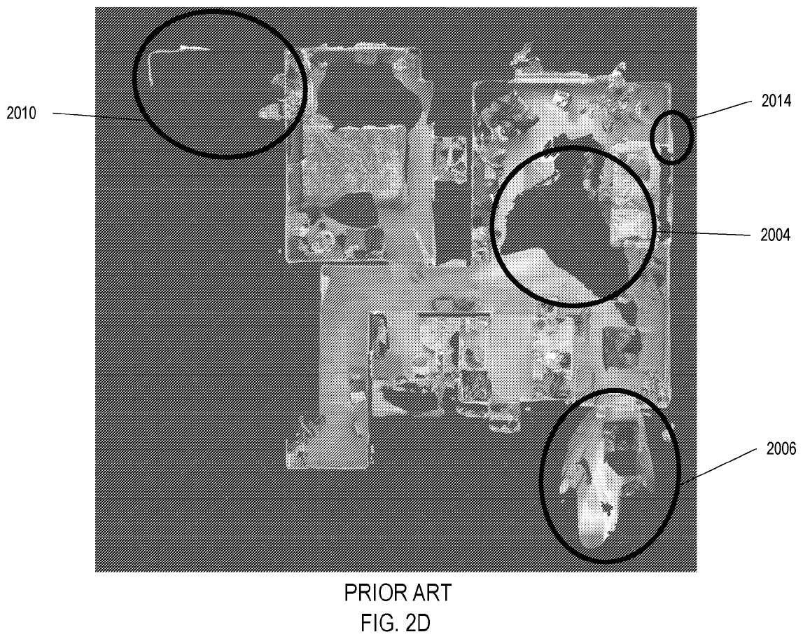

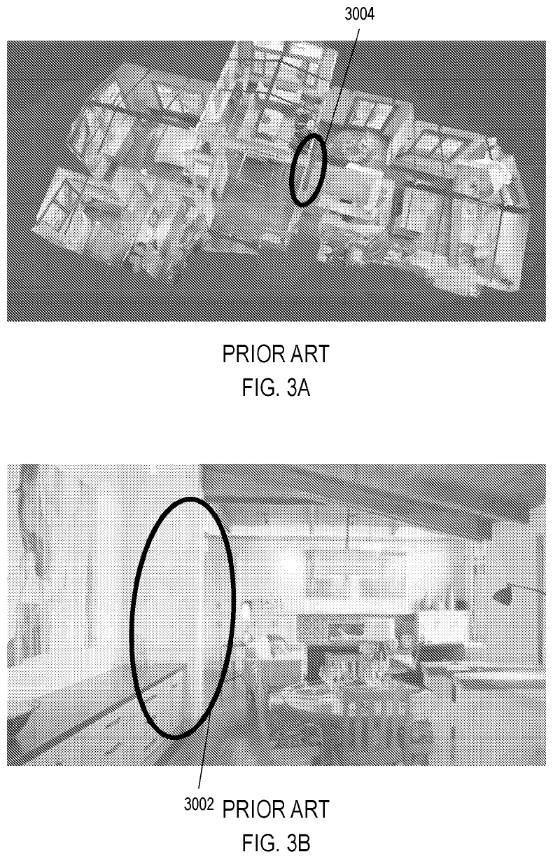

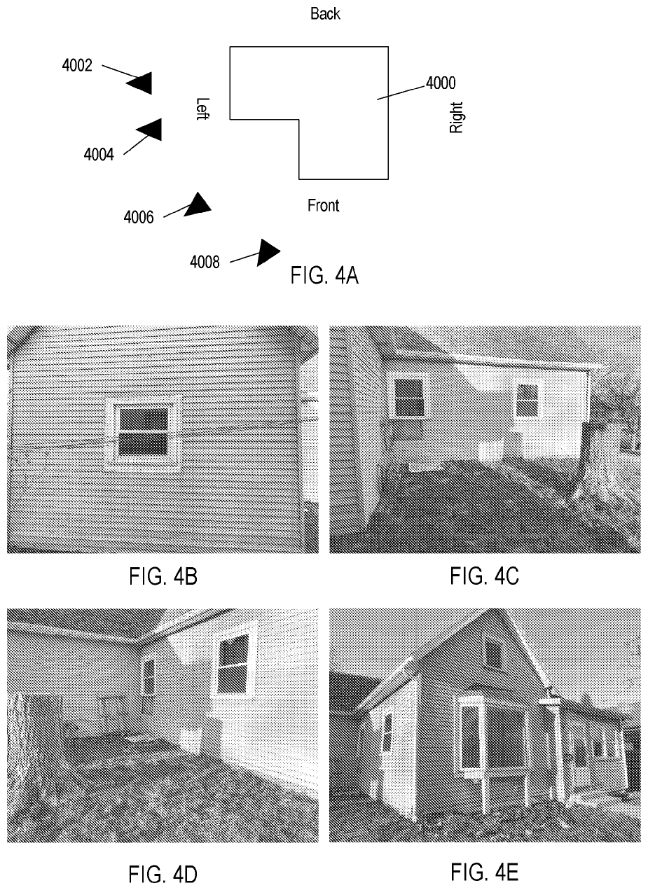

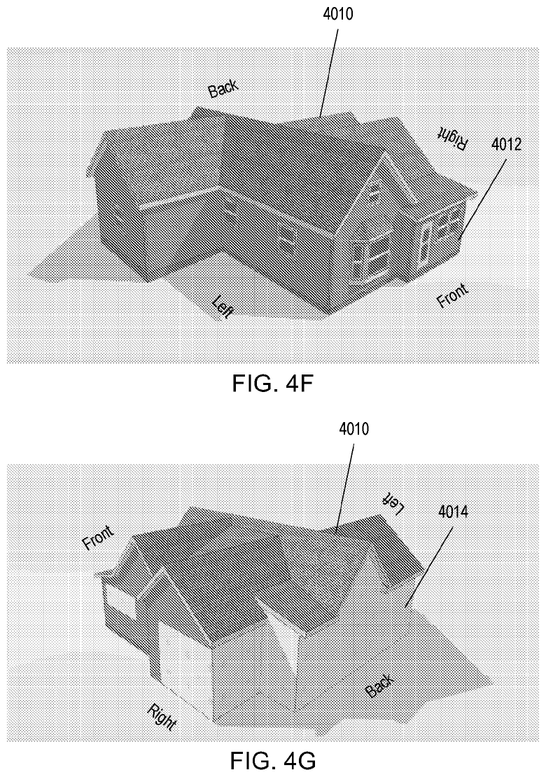

FIG. 4A illustrates a top down view of a capture (e.g., scan) process or phase of a 3D reconstruction process of an exterior, according to some embodiments. Structure 4000 is captured by a capture device at poses 4002-4008. FIGS. 4B-4E illustrate images captured by the capture device at poses 4002-4008, respectively. As illustrated in FIG. 4A, the capture device captures structure 4000 from the left and the front.

In some embodiments, there may be no images captured by the capture device from the right and the back of structure 4000 because those portions are simply not captured, inaccessible, occluded by elements such as foliage or vehicles, adjacent to other structures, and the like.

The images illustrated in FIGS. 4B-4E captured by the capture device are used to generate 3D model 4010 illustrated in FIGS. 4F-4G. Since the capture device captured images of structure 4000 from the left and the front, model 4010 constructed from the captured images will be complete from the left and the front. Since the capture device did not capture images of structure 4000 from the right and the back, model 4010 constructed from the captured images will be incomplete from the right and the back.

FIG. 4F illustrates a front-left view of model 4010 and FIG. 4G illustrates a back-right view of model 4010. Modeled portions 4012 are portions of 3D model 4010 that are modeled based on the images captured by the capture device from the left and the front of structure 4000. Unmodeled portions 4014 are portions of 3D model 4010 that are unmodeled as there are no images captured by the capture device from the right and the back of structure 4000. In some embodiments, for example as illustrated in FIG. 4G, unmodeled portions 4014 are predicted geometries of surfaces.

3D capturing or scanning techniques can be prone to errors such as tracking error and drift. Tracking error can manifest when a scanner (e.g., 3D scanner or 2D scanner) implementing capturing or scanning techniques (e.g., 3D scanning techniques or 2D scanning techniques) loses track of its location in the environment. For example, the scanner can lose track of its location in an environment that lacks features, such as in a hallway. All sensors produce measurement errors. The measurement errors can be amplified in capturing or scanning techniques that rely on previous sensor values to determine current sensor values. Drift is the deviation of sensor values over time due to accumulated measurement errors.

Errors such as tracking error and drift can be minimized by capturing or scanning the environment one space at a time and combining the scans of each space into an aggregate scan that represents the environment. One space at a time capturing or scanning may minimize errors such as tracking error and drift, but may not maintain the relationship between the spaces and thus lead to an inaccurate aggregate scan.

Augmenting one set of data (e.g., 3D data or 2D data) or one model (e.g., 3D model or 2D model) with another set of data (e.g., 3D data or 2D data) or another model (e.g., 3D model or 2D model) can address some of the aforementioned issues. Augmenting one set of data or one model with another set of data or another model can be used to revise, refine, or complete, the data or the models. The disclosure primarily relates to augmenting 3D data with a 3D model. One of ordinary skill in the art will appreciate that the principles disclosed herein can apply to various other combinations of augmentations between 2D data, 2D models, 3D data, and 3D models.

In some examples, 3D data of an interior environment can be augmented with 3D data of an exterior environment, 3D data of an interior environment can be augmented with a 3D model of an exterior environment, a 3D model of an interior environment can be augmented with 3D data of an exterior environment, a 3D model of an interior environment can be augmented with a 3D model of an exterior environment, and the like. One of ordinary skill in the art will appreciate various other combinations of augmentations between 2D data, 2D models, 3D data, and 3D models.

Augmenting one set of data or one model with another set of data or another model can include correlating or mapping, aligning, deforming, scaling, cropping, hole filling (e.g., completing), and the like. In some embodiments, augmenting one set of data or model with another set of data or another model includes solving an optimization problem that includes finding the optimal solution from all feasible or possible solutions, for example given one or more constraints.

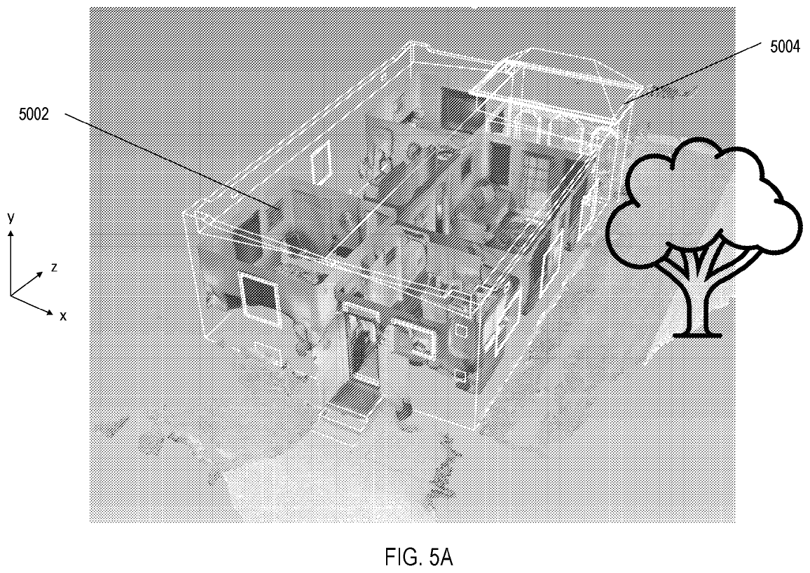

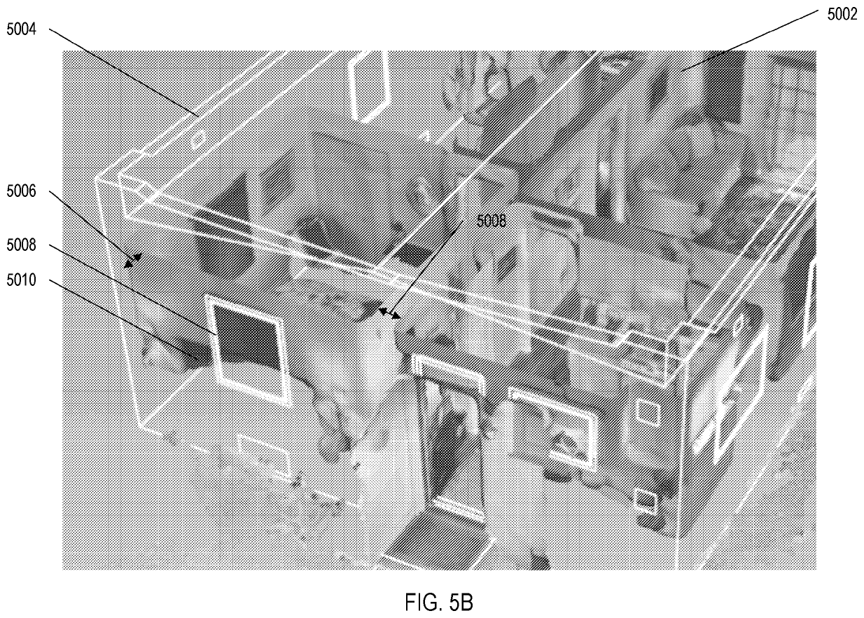

FIG. 5A illustrates interior 3D data 5002 augmented with exterior 3D model 5004, according to some embodiments. FIG. 5B illustrates a magnified view of a portion of FIG. 5A, according to some embodiments. In some embodiments, interior 3D data 5002 and exterior 3D model 5004 can be captured or generated using a single 3D reconstruction process. In some embodiments, interior 3D data 5002 and exterior 3D model 5004 can be captured or generated using multiple, separate 3D reconstruction processes. In one example, interior 3D data 5002 can be captured using one 3D reconstruction process and exterior 3D model 5004 can be generated using another 3D reconstruction process.

Although the example illustrated in FIGS. 5A-5B and the disclosure herein is in relation to interior 3D data and an exterior 3D model, one of ordinary skill in the art will appreciate the principles described herein apply to other configurations (e.g., 3D data and 3D data, 3D data and 3D model, 3D model to 3D model, etc.).

Interior 3D data 5002 and exterior 3D model 5004 include one or more elements. In some embodiments, the elements are associated with a building object. In some embodiments, the elements are associated with a structure of interest, for example of the building object. Examples of elements associated with a structure of interest include portals (e.g., doors, windows, openings), interior walls, exterior walls, surfaces of the structure, and the like. In some embodiments, the elements are not associated with a structure of interest, for example of the building object. Examples of elements not associated with a structure of interest include vehicles, utility poles, trees, foliage, other structures, and the like, that are not associated with the building object.

Elements of interior 3D data 5002, exterior 3D model 5004, or both can be identified. Identifying the elements can be a manual, semi-automatic, or fully automatic process. Identifying the elements can include semantic segmentation and labeling or object recognition.

Interior 3D data 5002, or portions thereof, can be augmented with exterior 3D model 5004, or portions thereof. Augmenting interior 3D data 5002 with exterior 3D model 5004 can include correlating or mapping, aligning, deforming, scaling, cropping, hole filling (e.g., completing), and the like.

In some embodiments, the augmenting can include generating a common coordinate system for interior 3D data 5002 and exterior 3D model 5004. Interior 3D data 5002 can have an associated coordinate system (e.g., an interior coordinate system) and exterior 3D model 5004 can have an associated coordinate system (e.g., an exterior coordinate system). The common coordinate system can be generated based on the interior coordinate and the exterior coordinate system. In some embodiments, the common coordinate system can be generated by matching the interior coordinate system with the exterior coordinate system, or vice versa.

In some embodiments, the augmenting can be based on location information associated with interior 3D data 5002 and exterior 3D model 5004. Examples of location information include latitude, longitude, elevation, and the like. Interior 3D data 5002 can be augmented with exterior 3D model 5004 relative to a common coordinate system based at least in part on location information.

In some embodiments, the augmenting can be based on one or more sides associated with interior 3D data 5002 and exterior 3D model 5004 where the sides correspond to the sides of the underlying building structure. For example, interior 3D data 5002 can have a front side and exterior 3D model 5004 can have a front side. In these embodiments, interior 3D data 5002 and exterior 3D model 5004 can be augmented by substantially aligning the front side of interior 3D data 5002 and the front side of exterior 3D model 5004 in a common coordinate system. In some embodiments, the sides can be established or identified based on identified elements and their generally associated sides. In some examples, a building structure may have several exterior doors, where a hinged door may be associated with a front side, and where a sliding door may be associated with a back side. In some examples, a building structure may have several exterior windows, where a bay window may be associated with a front side.

In some embodiments, the augmenting can be based on an outline of interior 3D data 5002 and an outline of exterior 3D model 5004. In these embodiments, the outline of interior 3D data 5002 is substantially aligned with the outline of exterior 3D model 5004, for example, based on one or more common architectural elements such as windows, and preferably those with industry standard attributes, such as doors, or based on one or more values derived from the architectural elements. In some examples, a door of the outline of interior 3D data 5002 can be matched to a corresponding door of the outline of exterior 3D model 5004, and the outline of interior 3D data 5002 can be substantially aligned with the outline of exterior 3D model 5004 based on the matched door. In some examples, a door of interior 3D data 5002 can be matched to a corresponding door of exterior 3D model 5004, interior 3D data 5002 can be substantially aligned with exterior 3D model 5004 based on the matched doors, an exterior wall thickness (i.e., thickness of the wall between interior 3D data 5002 and exterior 3D model 5004) can be derived based on the substantial alignment of interior 3D data 5002 with exterior 3D model 5004, and the outline of interior 3D data 5002 can be substantially aligned with the outline of exterior 3D data 5004 based on the derived exterior wall thickness.

In some embodiments, one or more architectural elements are substantially aligned according to axis alignment between the architectural elements of the two data sources. In some embodiments, this occurs after generating a common coordinate system. In some embodiments, axis alignment of matching architectural elements, or features thereof, generates the common coordinate system. For example, a window of 3D data 5002 having a planar orientation in an x-y plane is substantially aligned with the borders with a window of 3D model 5004 having matching planar orientation according to axes orientations. For planar architectural elements, in some examples this means two axes of the matching architectural elements are at least parallel to each other with corresponding points or features of the architectural element falling on the third orthogonal axis. For example, the x-axis of a window in 3D data 5002 is parallel to the x-axis of a window in 3D model 5004, and the y-axis of a window in 3D data 5002 is parallel to the y-axis of a window in 3D model 5004, with the corners of the window each falling on the z-axis. Though architectural elements may substantially align with one another in such way, they are unlikely to perfect overlay one another due to distal surface separation. While axis alignment is discussed, point alignment or generation of lines between points may follow similar steps. In some embodiments, the one or more substantially aligned architectural elements are orthogonal to one another.

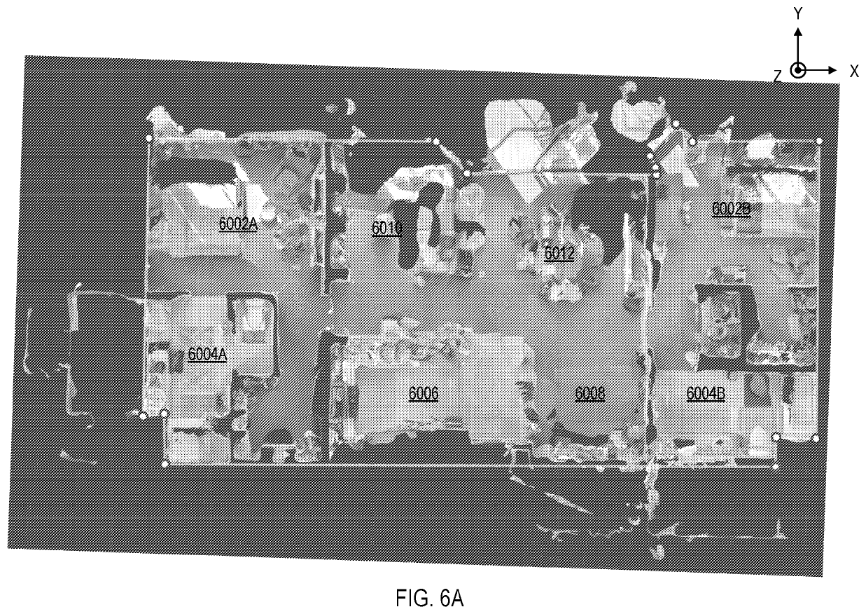

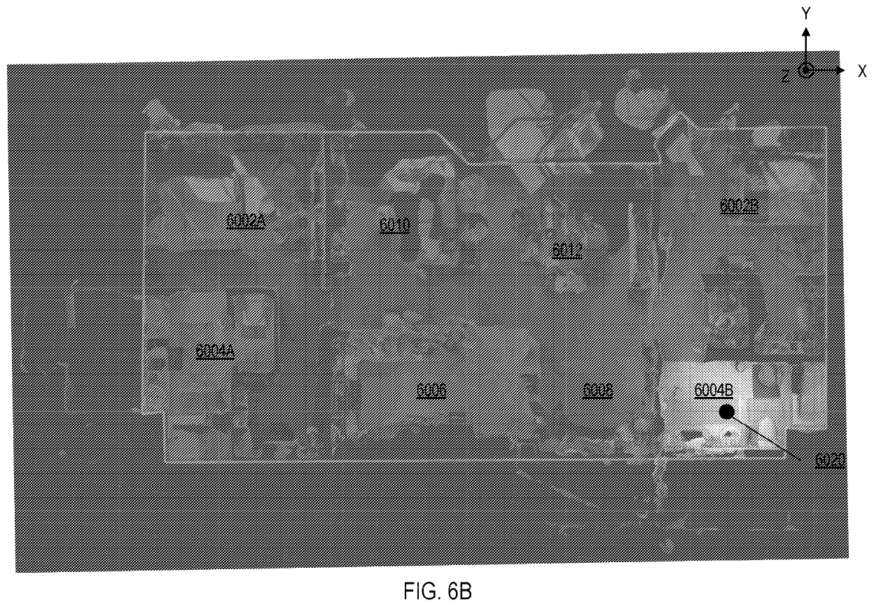

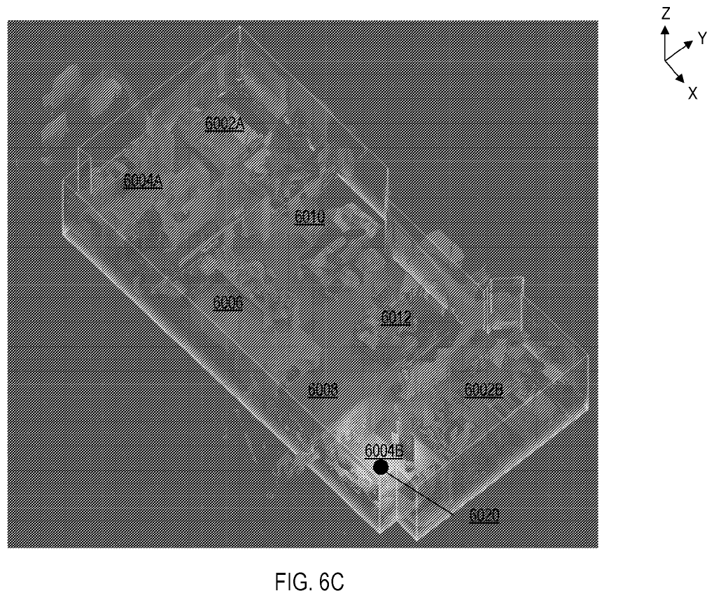

Outline of interior 3D data 5002 can be generated based on a top-down view of interior 3D data 5002. Referring briefly to FIG. 6A, it illustrates a top-down view of interior 3D data, according to some embodiments. Interior 3D data 5002 of FIGS. 5A-5B are of a different interior than interior 3D data of FIGS. 6A-6C. Outline of exterior 3D model 5004 can be generated based on a top-down view of exterior 3D model 5004.

In some embodiments, the augmenting can be based on one or more elements common to interior 3D data 5002 and exterior 3D model 5004. In some embodiments, the elements are associated with a building object. In some embodiments, the elements are associated with a structure of interest, for example of the building object. For example, interior 3D data 5002 can be augmented with exterior 3D model 5004 based on doors or windows that are common to the building object. In some embodiments, the elements are not associated with a structure of interest, for example of the building object. For example, interior 3D data 5002 can be augmented with exterior 3D model 5004 based on vehicles, utility poles, trees, foliage, other structures, and the like, that are not associated with the building object.

In some embodiments, the augmenting based on elements common to interior 3D data 5002 and exterior 3D model 5004 can include identifying an aspect (e.g., plane) of an element of interior 3D data 5002 (such as by semantic segmentation or object recognition), identifying corresponding aspect (e.g., plane) of a corresponding element of exterior 3D model 5004 (such as by semantic segmentation or object recognition), and substantially aligning the aspect of the element of interior 3D data 5002 with the corresponding aspect of the corresponding element of exterior 3D model 5004. In some embodiments, substantially aligning the aspect of the element of interior 3D data 5002 with the corresponding aspect of the corresponding element of exterior 3D data 5004 can be based on one or more assumptions. Examples of assumptions include door thickness, window thickness, wall thickness, and other anchoring aspects common to interior 3D data 5002 and exterior 3D model 5004.

In some embodiments, the augmenting can be used to compensate for limitations of different capturing or scanning techniques, different reconstructions techniques, different modeling techniques, or a combination thereof. In some embodiments, the capturing or scanning technique, the reconstruction technique, the modeling technique, or a combination thereof, related to a first data capture may cause lines that are straight in the environment to appear wavy, broken, or disjointed in the resultant reconstructed output (such as interior 3D data 5002); however, the capturing scanning technique, the reconstruction technique, the modeling technique, or a combination thereof, related to a second data capture may cause the corresponding lines in the resultant modeled output (such as exterior 3D model 5004) to appear be straight. For example, an interior 3D model generated from interior 3D data 5002, which can be a mesh input, may include lines that are wavy, broken, or disjointed; however, exterior 3D model 5004, which can be generated from primitive based modeling, may include straight lines. In some embodiments, the augmenting can be used to compensate for potentially problematic surfaces in the environment. For example, potentially problematic surfaces in an interior portion of the environment can lead to duplicative elements, missing data, or additional data in interior 3D data 5002; however, an exterior portion of the environment may not include the same potentially problematic surfaces and therefore exterior 3D model 5004 may not include the same duplicative elements, missing data, or additional data. Augmenting interior 3D data 5002 with exterior 3D data 5004 can correct the distortions in interior 3D data 5002 based on exterior 3D data 5004.

In some embodiments, the correlating or mapping can include assigning confidence values to elements in interior 3D data 5002, exterior 3D model 5004, or both. Elements can include points, surfaces, and the like. In some embodiments, high confidence values can be assigned to elements that are common to both interior 3D data 5002 and exterior 3D model 5004, and, in some embodiments, low confidence values can be assigned to all other elements. In some embodiments, the confidence values are based on co-visibility of the elements in interior 3D data 5002 and exterior 3D model 5004. For example, high confidence values can be assigned to doors and windows that are visible in both interior 3D data 5002 and exterior 3D model 5004. In some embodiments, the confidence values are based on commonality of the elements in interior 3D data 5002 and exterior 3D model 5004, which may not necessarily be co-visible in interior 3D data 5002 and exterior 3D model 5004. For example, high confidence values can be assigned to peripheral surfaces (e.g., interior walls) of interior 3D data 5002 that are common to surfaces (e.g., exterior walls) of exterior 3D model 5004.

In some embodiments, the augmenting can include identifying, correlating, and substantially aligning common elements in interior 3D data 5002 and exterior 3D model 5004, and revising interior 3D data 5002, exterior 3D model 5004, or both, based on the correlation or alignment.

In one example referring to FIGS. 5A and 5B, interior 3D data 5002 can include a portion of window 5008 and headboard 5010 directly below the portion of window 5008, and exterior 3D model 5004 can include all of window 5008. Window 5008 in interior 3D data 5002 and window 5008 in exterior 3D model 5004 can be correlated and aligned, and the portion of window 5008 in interior 3D data 5002 can be revised (e.g., filled in) based on window 5008 in exterior 3D model 5004.

Referring briefly to FIGS. 4A-4G, as described here, unmodeled portions 4014 are predicted geometries of surfaces. In this example, unmodeled portions 4014 are predicted geometries based on images illustrated in FIGS. 4B-4E. In some embodiments, unmodeled portions 4014 are predicted geometries based on images illustrated in FIGS. 4B-4E in further view of interior 3D data, an interior 3D model, or both, of structure 4000. For example, elements such as windows and doors that are common to both (exterior) model 4010 and the interior model can be used to correlate and align model 4010 and the interior model. The common elements may be those that are at the front and the left of structure 4000. Model 4010 can be revised based on the correlation or alignment of the common elements. For example, unmodeled portions 4014 can be generated or filled in, for example with windows, doors, and the like, that are in the interior model.

Interior 3D data 5002 can be offset from exterior 3D model 5004, for example, based on one or more common architectural elements such as windows, and preferably those with industry standard attributes, such as doors, or based on one or more values derived from the architectural elements. In some examples, a door of interior 3D data 5002 can be matched to a corresponding door of exterior 3D model 5004, and interior 3D data 5002 can be offset from exterior 3D model 5004 based on an assumed thickness of the matched door (as doors are typically set to manufacturer and industry standards for consistency). In some examples, a door of interior 3D data 5002 can be matched to a corresponding door of exterior 3D model 5004, interior 3D data 5002 can be substantially aligned with exterior 3D model 5004 based on the matched doors, an exterior wall thickness (i.e., thickness of the wall between interior 3D data 5004 and exterior 3D model 5004) can be derived based on the substantial alignment of interior 3D data 5002 with exterior 3D model 5004, and interior 3D data 5002 can be offset from exterior 3D data 5004 based on the derived exterior wall thickness. Wall offset 5006 is an example of an offset of interior 3D data 5002 relative to exterior 3D model 5004.

In some embodiments, interior 3D data 5002 can be captured following a one space at a time approach in which each space (e.g., room) is captured or scanned one at a time and the scans of each space are combined into an aggregate scan that represents the environment. As mentioned above, capturing or scanning in this way may not maintain the relationship between the spaces. One way to reintroduce the relationship between the spaces in interior 3D data 5002 can be my leveraging exterior 3D model 5004. In some embodiments, the spaces in interior 3D data 5002 can be pulled apart or dilated based on exterior 3D model 5004 and, for example, aligning common one or more architectural elements. Pulling apart or dilating interior 3D data 5002 based on exterior 3D model 5004 in this manner can introduce interior wall offsets that are not present in the interior 3D data 5002 at the time of capture/aggregation.

In some embodiments, interior 3D data 5002, exterior 3D model 5004, both, or portions thereof, a coordinate system associated with interior 3D data 5002 (e.g., an interior coordinate system), a coordinate system associated with exterior 3D model 5004 (e.g., exterior coordinate system), or both, or a combination thereof, can be scaled based on one or more derived scaling factors. In some embodiments, an interior scaling factor can be derived from interior 3D data 5002, interior coordinate system, or both, and interior 3D data 5002, interior coordinate system, exterior 3D model 5004, exterior coordinate system, or a combination thereof can be scaled based on the derived interior scaling factor. Similarly, in some embodiments, an exterior scaling factor can be derived from exterior 3D model 5004, exterior coordinate system, or both, and exterior 3D model 5004, exterior coordinate system, interior 3D data 5002, interior coordinate system, or a combination thereof can be scaled based on the derived exterior scaling factor. In some embodiments, an interior scaling factor can be derived from interior 3D data 5002, interior coordinate system, or both, interior 3D data 5002, interior coordinate system, or both can be scaled based on the derived interior scaling factor, an exterior scaling factor can be derived based on the interior scaling factor, the scaled interior 3D data 5002, the scaled interior coordinate system, or a combination thereof, and exterior 3D model, exterior coordinate system, or both can be scaled based on the derived exterior scaling factor. Similarly, in some embodiments, an exterior scaling factor can be derived from exterior 3D model 5004, exterior coordinate system, or both, exterior 3D model 5004, exterior coordinate system, or both can be scaled based on the derived exterior scaling factor, an interior scaling factor can be derived from the exterior scaling factor, the scaled exterior 3D model 5004, the scaled exterior coordinate system, or both, and interior 3D data 5002, interior coordinate system, or both can be scaled based on the derived interior scaling factor.

In some embodiments, a quality metric, a confidence value, or both, can be derived for and associated with interior 3D data 5002 and exterior 3D model 5004. The quality metric or confidence value can be based on the capturing or scanning technique, the reconstruction technique, the modeling technique, or a combination thereof. Different capturing or scanning techniques, reconstruction techniques, modeling techniques, or combinations thereof, can introduce different artifacts which can contribute to the quality metric or confidence value. In some examples, a visual data based capturing or scanning technique may have a low quality metric or confidence value if the visual data is blurry, for example due to motion blur. In some examples, depth data based capturing or scanning techniques may have a low quality metric or confidence value if the depth data includes artifacts, for example due to reflective surfaces, dark surfaces, or clear or transparent surfaces. In some examples, visual data, depth data, or both from a ground-level imager may have a relatively high quality metric or high confidence value, and visual data, depth data, or both, from an aerial imager may have a relatively low quality metric or a low confidence value. In these examples, the quality metric or the confidence value may be a function of distance from imager to subject. In some examples, a 2D model such as an architectural plan may have a relatively high quality metric or high confidence value and a 2D model such as a floor planed generated from visual data, depth data, or both, may have a relatively low quality metric or a low confidence value. In some examples, a 3D model generated from an architectural plan may have a relatively high quality metric or high confidence value and a 3D model generated from visual data, depth data, or both, may have a relatively low quality metric or low confidence value. In these embodiments, the data/model with a higher quality metric or confidence value can be used as the base data/model. For example, if interior 3D data 5002 has a higher quality metric or confidence value, interior 3D data 5002 can be the base data/model and in this example, an interior scaling factor can be derived from interior 3D data 5002, interior 3D data 5002 can be scaled based on the derived interior scaling factor, an exterior scaling factor can be derived based on the interior scaling factor, and exterior 3D model can be scaled based on the derived exterior scaling factor. Similarly, if exterior 3D model 5004 has a higher quality metric or confidence value, exterior 3D model 5004 can be the base data/model and in this example, an exterior scaling factor can be derived from exterior 3D model 5004, exterior 3D model 5004 can be scaled based on the derived exterior scaling factor, an interior scaling factor can be derived from the exterior scaling factor, and interior 3D data 5002 can be scaled based on the derived interior scaling factor.

In some embodiments, deriving one scaling factor from another (e.g., deriving an exterior scaling factor from an interior scaling factor or deriving an interior scaling factor from an exterior scaling factor) can include calculating a conversion factor to be applied to one scaling factor to derive another. In one example, deriving an exterior scaling factor from an interior scaling factor can include calculating a conversion factor to be applied to the interior scaling factor to derive the exterior scaling factor. Similarly, in one example, deriving an interior scaling factor from an exterior scaling factor can include calculating a conversion factor to be applied to the exterior scaling factor to derive the interior scaling factor.

In some embodiments, deriving one scaling factor from another can be based on common elements. For example, an interior scaling factor can be derived for interior 3D data 5002, interior 3D data 5002 can be scaled based on the interior scaling factor, an exterior scaling factor can be derived from the interior scaling factor based on window 5008 which is common to both interior 3D data 5002 and exterior 3D model 5004, and exterior 3D model 5004 can be scaled based on the exterior scaling factor. Deriving the exterior scaling factor from the interior scaling factor based on window 5008 which is common to both interior 3D data 5002 and exterior 3D model 5004 can include scaling window 5008 of exterior 3D model 5004 until its dimensions match that of window 5008 of the scaled interior 3D data 5002.

In some embodiments, deriving one scaling factor from another can be based on one or more industry standards. For example, an interior scaling factor can be derived from interior 3D data 5002, interior 3D data 5002 can be scaled based on the interior scaling factor, an exterior scaling factor can be derived from the interior scaling factor such that exterior 3D model 5004 scaled based on the exterior scaling factor satisfies an industry standard exterior wall width/depth, and exterior 3D model 5004 can be scaled based on the exterior scaling factor.

In some embodiments, interior anchor poses for interior 3D data 5002 and exterior anchor poses for exterior 3D model 5004 are determined. A set of common anchor poses including anchor poses that are common to the interior anchor poses and the exterior anchor poses are determined.

As described herein, the 3D reconstruction process can include one or more subprocesses such as, for example, a reconstruction subprocess. The reconstruction subprocess can be manual, semi-automatic, or fully automatic. One or more tools may be used, for example by a human, in the reconstruction subprocess.

One example tool is an illuminating cursor. The illuminating cursor can be used to identify rooms or areas in 3D data. FIG. 6A illustrates a top-down view of a floorplan representation generated based on 3D data (sometimes referred to as raw, unprocessed, or unstructured 3D data), according to some embodiments. The floorplan representation includes first bedroom 6002A, second bedroom 6002B, first bathroom 6004A, second bathroom 6004B, kitchen 6006, dining area 6008, living room 6010, and home office 6012.

FIG. 6B illustrates a top-down view of a floorplan representation and augmented 3D data, according to some embodiments. FIG. 6C illustrates a perspective view of a floorplan representation and augmented 3D data, according to some embodiments. In some embodiments, augmentation of the 3D data illustrated in FIG. 6A is a function of distance from cursor 6020. In some embodiments, cursor 6020 has a 3D position (X, Y, Z). Rays can be casted in all directions from a position of cursor 6020. In some embodiments, the rays that are casted from the position of cursor 6020 can be of a predetermined length. In some embodiments, the first 3D data that the ray intersects can be augmented. In other words, if rays casted from cursor 6020 intersect 3D data, then that 3D data can be augmented. In some embodiments, the 3D data that is not the first 3D data can also be augmented. The augmentation can include, for example, brightness, opacity, and the like. Augmenting the 3D data in this manner can be a useful tool in assisting a human to identify and label the 3D data.

IMU can include, among other components, one or more gyroscopes. A gyroscope measures rotation about a known point. Gyroscope measurements can drift over time due to integration of imperfections and noise within the gyroscope or, more generally, the IMU. Of the row axis, the pitch axis, and the yaw axis, it is the yaw axis that is most sensitive to drift. The drift can cause angular error. The angular error can be measured in degrees of rotation per unit of time.

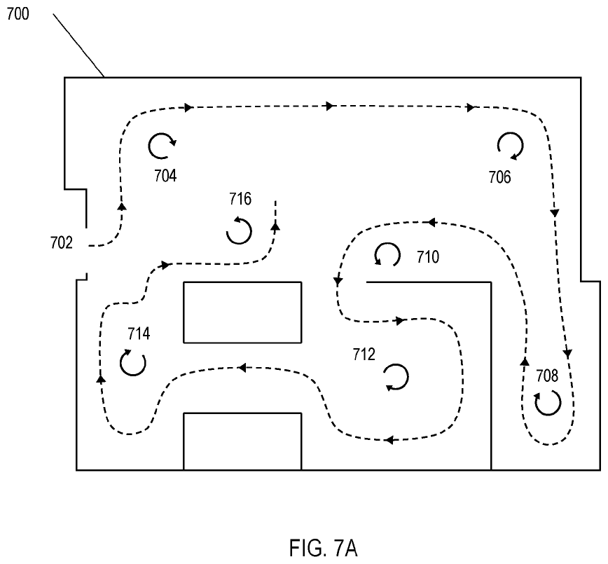

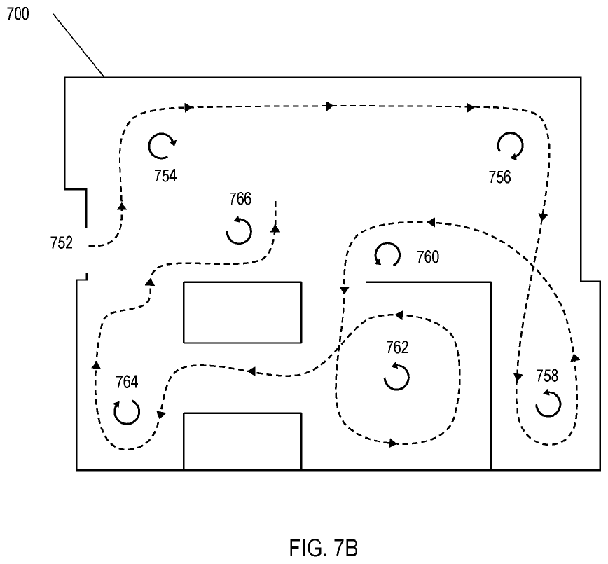

FIGS. 7A and 7B illustrate floorplan 700 with capture path 702 and capture path 752, respectively, according to some embodiments. Each capture path can include one or more rotations (sometimes referred to as scan directions).

An angular error of a capture path can be related to or a function of an angular error of each rotation of the capture path. For example, the angular error of a capture path can be an accumulation of angular errors the rotations of the capture path. The angular error of each rotation can have an associated magnitude and direction. Similarly, the angular error of the capture path can also have an associated magnitude and direction.

The capture path can include clockwise rotations and counterclockwise rotations. Each clockwise rotation can result in a positive angular error and each counterclockwise rotation can result in a negative angular error.

Capture path 702 includes clockwise rotations 704, 706, 708, 712, and 714, and counterclockwise rotations 710 and 716. For the sake of simplicity, assuming the angular error of each rotation is of equal magnitude, the angular error of capture path 702 can be very positive.

Capture path 752 includes clockwise rotations 754, 756, and 764, and counterclockwise rotations 758, 760, 762, and 766. For the sake of simplicity, assuming the angular error of each rotation is of equal magnitude, the angular error of capture path 752 can be slightly negative.

In some embodiments, the 3D reconstruction process can include determining and displaying a recommended or suggested rotation during 3D scanning, for example, in an effort to minimize drift or angular error. In some embodiments, determining a recommended or suggested rotation can be based on one or more previous rotations. For example, determining a recommended or suggested rotation can be based on the magnitude, the direction, or both, of one or more previous rotations. In some embodiments, determining recommended or suggested rotations can be based on an angular error of one or more previous rotations. For example, determining a recommended or suggested rotation can be based on the magnitude, the direction, or both, of the angular error of one or more previous rotations.

For example, with reference to capture paths 702 and 752, at the start of capture paths 702 and 752, the angular error is zero. At clockwise rotation 704 of capture path 702 and clockwise rotation 754 of capture path 752, the angular error is slightly positive. At this point, a counterclockwise recommended or suggested rotation can be determined and displayed. The counterclockwise recommended or suggested rotation is in the opposite direction of the clockwise rotation 704 of capture path 702 and the clockwise rotation 754 of capture path 752 in an effort to lower the angular error from slightly positive to closer to zero. At clockwise rotation 706 of capture path 702 and clockwise rotation 756 of capture path 756, the angular error is slightly more positive. The counterclockwise recommended or suggested rotation is not followed. At this point, a counterclockwise recommended or suggested rotation can be determined and displayed. The counterclockwise recommended or suggested rotation is in the opposite direction of the clockwise rotations 704 and 706 of capture path 702 and clockwise rotations 754 and 756 of capture path 702 in an effort to lower the angular error from slightly more positive to closer to zero. If the counterclockwise recommended or suggested rotation is not followed, the next rotation is a clockwise rotation as illustrated by clockwise rotation 708 of capture path 702. If the counterclockwise recommended or suggested rotation is followed, the next rotation is a counterclockwise rotation as illustrated by counterclockwise rotation 758 of capture path 752.

The 3D data can include private information in the environment. Examples of private information include personally identifiable information, pictures, medications, assistive devices or equipment, and the like. The 3D data can be filtered to obfuscate the private information in the environment. Filtering can include identifying, blurring, distorting, pixelating, and the like.

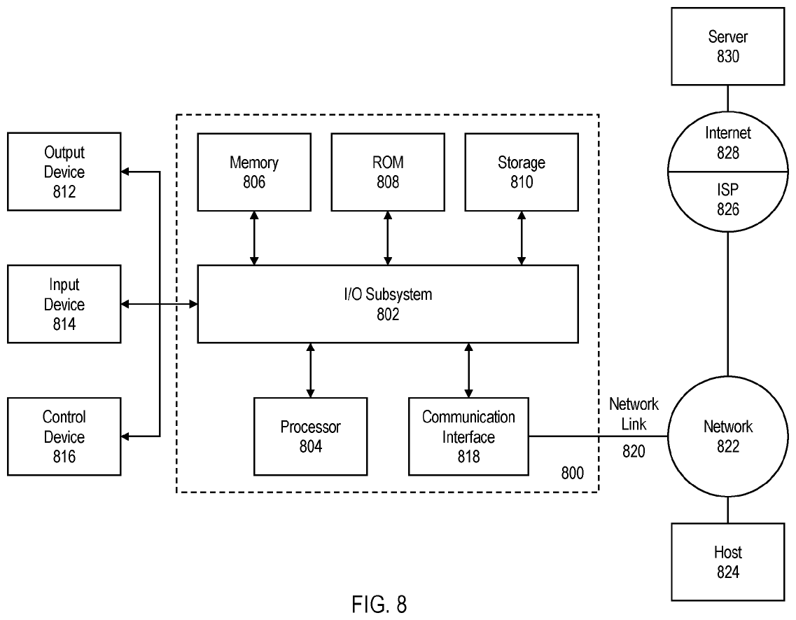

FIG. 8 illustrates a computer system 800 configured to perform any of the steps described herein. The computer system 800 includes an input/output (I/O) Subsystem 802 or other communication mechanism for communicating information, and a hardware processor, or multiple processors, 804 coupled with the I/O Subsystem 802 for processing information. The processor(s) 804 may be, for example, one or more general purpose microprocessors.

The computer system 800 also includes a main memory 806, such as a random access memory (RAM), cache and/or other dynamic storage devices, coupled to the I/O Subsystem 802 for storing information and instructions to be executed by processor 804. The main memory 806 also may be used for storing temporary variables or other intermediate information during execution of instructions to be executed by the processor 804. Such instructions, when stored in storage media accessible to the processor 804, render the computer system 800 into a special purpose machine that is customized to perform the operations specified in the instructions.

The computer system 800 further includes a read only memory (ROM) 808 or other static storage device coupled to the I/O Subsystem 802 for storing static information and instructions for the processor 804. A storage device 810, such as a magnetic disk, optical disk, or USB thumb drive (Flash drive), etc., is provided and coupled to the I/O Subsystem 802 for storing information and instructions.

The computer system 800 may be coupled via the I/O Subsystem 802 to an output device 812, such as a cathode ray tube (CRT) or LCD display (or touch screen), for displaying information to a user. An input device 814, including alphanumeric and other keys, is coupled to the I/O Subsystem 802 for communicating information and command selections to the processor 804. Another type of user input device is control device 816, such as a mouse, a trackball, or cursor direction keys for communicating direction information and command selections to the processor 804 and for controlling cursor movement on the output device 812. This input/control device typically has two degrees of freedom in two axes, a first axis (e.g., x) and a second axis (e.g., y), that allows the device to specify positions in a plane. In some embodiments, the same direction information and command selections as cursor control may be implemented via receiving touches on a touch screen without a cursor.

The computing system 800 may include a user interface module to implement a GUI that may be stored in a mass storage device as computer executable program instructions that are executed by the computing device(s). The computer system 800 may further, as described below, implement the techniques described herein using customized hard-wired logic, one or more ASICs or FPGAs, firmware and/or program logic which in combination with the computer system causes or programs the computer system 800 to be a special-purpose machine.

According to some embodiment, the techniques herein are performed by the computer system 800 in response to the processor(s) 804 executing one or more sequences of one or more computer readable program instructions contained in the main memory 806. Such instructions may be read into the main memory 806 from another storage medium, such as storage device 810. Execution of the sequences of instructions contained in the main memory 806 causes the processor(s) 804 to perform the process steps described herein. In some embodiments, hard-wired circuitry may be used in place of or in combination with software instructions.

Various forms of computer readable storage media may be involved in carrying one or more sequences of one or more computer readable program instructions to the processor 804 for execution. For example, the instructions may initially be carried on a magnetic disk or solid state drive of a remote computer. The remote computer can load the instructions into its dynamic memory and send the instructions over a telephone line, cable, using a modem (or optical network unit with respect to fiber). A modem local to the computer system 800 can receive the data on the telephone line and use an infra-red transmitter to convert the data to an infra-red signal. An infra-red detector can receive the data carried in the infra-red signal and appropriate circuitry can place the data on the I/O Subsystem 802. The I/O Subsystem 802 carries the data to the main memory 806, from which the processor 804 retrieves and executes the instructions. The instructions received by the main memory 806 may optionally be stored on the storage device 810 either before or after execution by the processor 804.

The computer system 800 also includes a communication interface 818 coupled to the I/O Subsystem 802. The communication interface 818 provides a two-way data communication coupling to a network link 820 that is connected to a local network 822. For example, the communication interface 818 may be an integrated services digital network (ISDN) card, cable modem, satellite modem, or a modem to provide a data communication connection to a corresponding type of telephone line. As another example, the communication interface 818 may be a local area network (LAN) card to provide a data communication connection to a compatible LAN (or WAN component to communicated with a WAN). Wireless links may also be implemented. In any such implementation, the communication interface 818 sends and receives electrical, electromagnetic or optical signals that carry digital data streams representing various types of information.

The network link 820 typically provides data communication through one or more networks to other data devices. For example, the network link 820 may provide a connection through the local network 822 to a host computer 824 or to data equipment operated by an Internet Service Provider (ISP) 826. The ISP 826 in turn provides data communication services through the world-wide packet data communication network now commonly referred to as the “Internet” 828. The local network 822 and the Internet 828 both use electrical, electromagnetic or optical signals that carry digital data streams. The signals through the various networks and the signals on the network link 820 and through the communication interface 818, which carry the digital data to and from the computer system 800, are example forms of transmission media.

The computer system 800 can send messages and receive data, including program code, through the network(s), the network link 820 and the communication interface 818. In the Internet example, a server 830 might transmit a requested code for an application program through the Internet 828, the ISP 826, the local network 822 and communication interface 818.

The received code may be executed by the processor 804 as it is received, and/or stored in the storage device 810, or other non-volatile storage for later execution.

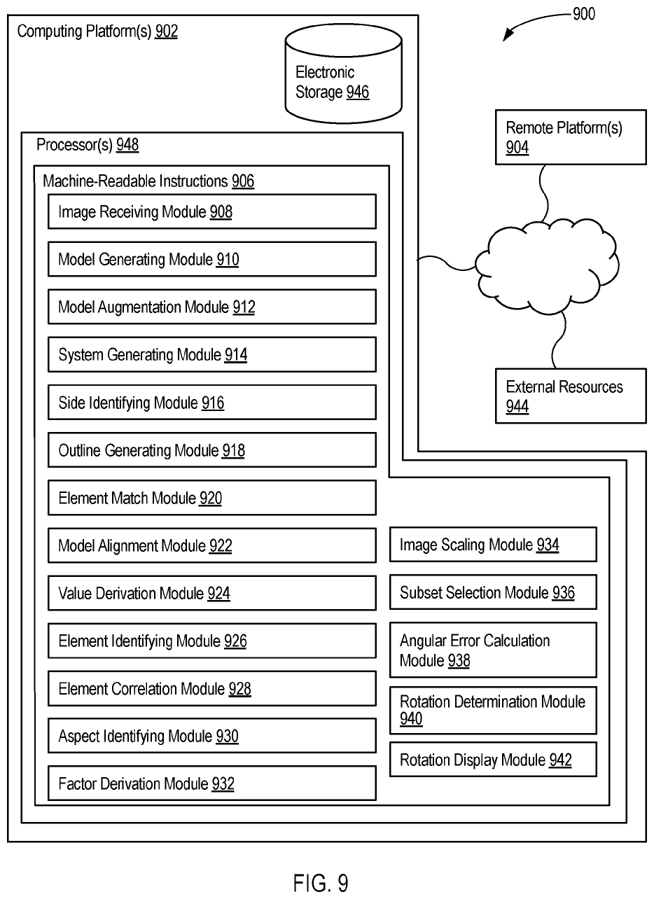

FIG. 9 illustrates a system 900 configured for augmenting 3D models, in accordance with one or more implementations. In some implementations, system 900 may include one or more computing platforms 902. Computing platform(s) 902 may be configured to communicate with one or more remote platforms 904 according to a client/server architecture, a peer-to-peer architecture, and/or other architectures. Remote platform(s) 904 may be configured to communicate with other remote platforms via computing platform(s) 902 and/or according to a client/server architecture, a peer-to-peer architecture, and/or other architectures. Users may access system 900 via remote platform(s) 904.

Computing platform(s) 902 may be configured by machine-readable instructions 906. Machine-readable instructions 906 may include one or more instruction modules. The instruction modules may include computer program modules. The instruction modules may include one or more of image receiving module 908, model generating module 910, model augmentation module 912, system generating module 914, side identifying module 916, outline generating module 918, element match module 920, model alignment module 922, value derivation module 924, element identifying module 926, element correlation module 928, aspect identifying module 930, factor derivation module 932, image scaling module 934, subset selection module 936, angular error calculation module 938, rotation determination module 940, rotation display module 942, and/or other instruction modules.

Image receiving module 908 may be configured to receive a first plurality of images. Image receiving module 908 may be configured to receive a second plurality of images. The first plurality of images and the second plurality of images may include at least one of visual data or depth data. The visual data may include at least one of image data or video data. By way of non-limiting example, the depth data may include at least one of point clouds, line clouds, meshes, or points. By way of non-limiting example, the first plurality of images and second plurality of images may be captured by one or more of a smartphone, a tablet computer, an augmented reality headset, a virtual reality headset, a drone, and an aerial platform.

Each image of the first plurality of images and the second plurality of images may include a building object. Each image of the first plurality of images may include an interior of the building object. Each image of the second plurality of images may include an exterior of the building object.

Model generating module 910 may be configured to generate a first 3D model based on the first plurality of images. Model generating module 910 may be configured to generate a second 3D model based on the second plurality of images. The first 3D model and the second 3D model may include at least one of a polygon-based model or a primitive-based model. The first 3D model and the second 3D model correspond to a building object. The first 3D model may correspond to an interior of the building object. The second 3D model may correspond to an exterior of the building object.

Model augmentation module 912 may be configured to augment the first 3D model with the second 3D model.

Augmenting the first 3D model with the second 3D model may be based on location information associated with associated with the first 3D model or the first plurality of images and the second 3D model or the second plurality of images. The location information may include latitude and longitude information.

System generating module 914 may be configured to generate the common coordinate system. Augmenting the first 3D model with the second 3D model may be relative to the common coordinate system. The first 3D model may be associated with a first coordinate system. The second 3D model may be associated with a second coordinate system. Generating the common coordinate system may be based on the first coordinate system and the second coordinate system. Generating the common coordinate system may include matching the first coordinate system with the second coordinate system.

Side identifying module 916 may be configured to identify a first plurality of sides of the first 3D model. Side identifying module 916 may be configured to identify a second plurality of sides of the second 3D model. Each side of the first plurality of sides and the second plurality of sides may correspond to a side of a building object. Augmenting the first 3D model with the second 3D model may include substantially aligning the first plurality of sides with the second plurality of sides in a common coordinate system.

Outline generating module 918 may be configured to generate the first outline of the first 3D model. Outline generating module 918 may be configured to generate the second outline of the second 3D model. Augmenting the first 3D model with the second 3D model may be based on a first outline of the first 3D model and a second outline of the second 3D model. Generating the first outline of the first 3D model may be based on a top-down view of the first 3D model. Generating the second outline of the second 3D model may be based on a top-down view of the second 3D model.

Augmenting the first 3D model with the second 3D model may include substantially aligning the first outline of the first 3D model with the second outline of the second 3D model. Model alignment module 922 may be configured to substantially align the first outline of the first 3D model with the second outline of the second 3D model. Model alignment module 922 may be configured to substantially aligning the first outline of the first 3D model with the second outline of the second 3D model may be based on one or more architectural elements. Substantially aligning the first outline of the first 3D model with the second outline of the second 3D model may be based on the matched architectural element. Model alignment module 922 may be configured to substantially aligning the first outline of the first 3D model with the second outline of the second 3D model may be based on one or more values derived from one or more architectural elements.

Element match module 920 may be configured to match an architectural element of the first 3D model with a corresponding architectural element of the second 3D model. Model alignment module 922 may be configured to substantially align the first 3D model with the second 3D model based on the matched architectural element. Value derivation module 924 may be configured to derive a value based on the substantial alignment of the first 3D model with the second 3D model. Model alignment module 922 may be configured to substantially aligning the first outline of the first 3D model with the second outline of the second 3D model may be based on the derived value.

Element match module 920 may be configured to match an architectural element of the first plurality of images with a corresponding architectural element of the second plurality of images. Model alignment module 922 may be configured to substantially align the first 3D model with the second 3D model based on the matched architectural element. Value derivation module 924 may be configured to derive a value based on the substantial alignment of the first 3D model with the second 3D model. Model alignment module 922 may be configured to substantially aligning the first outline of the first 3D model with the second outline of the second 3D model may be based on the derived value.

Element identifying module 926 may be configured to identify a first plurality of elements of the first 3D model. Element identifying module 926 may be configured to identify a second plurality of elements of the second 3D model. Identifying the first plurality of elements of the first 3D model may include semantically segmenting the first 3D model. Identifying the second plurality of elements of the second 3D model may include semantically segmenting the second 3D model. Identifying the first plurality of elements of the first 3D model may further include labeling the semantically segmented first 3D model. Identifying the second plurality of elements of the second 3D model may further include labeling the semantically segmented second 3D model. The first plurality of elements and the second plurality of elements may be associated with a building object. The first plurality of elements and the second plurality of elements may be associated with a structure of interest of the building object. The first plurality of elements and the second plurality of elements may be not associated with a building object. Element correlation module 928 may be configured to correlate the first plurality of elements with the second plurality of elements. Augmenting the first 3D model with the second 3D model may be based on the correlated plurality of elements.

Element identifying module 926 may be configured to identify a third plurality of elements. The third plurality of elements may include elements common to the first plurality of elements and the second plurality of elements. Augmenting the first 3D model with the second 3D model may be based on the third plurality of elements. The third plurality of elements may include elements common to the first plurality of elements and the second plurality of elements.

Aspect identifying module 930 may be configured to identify an aspect of an element of the first plurality of elements. Aspect identifying module 930 may be configured to identify a corresponding aspect of a corresponding element of the second plurality of elements. Augmenting the first 3D model with the second 3D model may include substantially aligning the aspect of the element of the first plurality of elements with the corresponding aspect of the corresponding element of the second plurality of elements. The aspect of the element of the first plurality of elements and the corresponding aspect of the corresponding element of the second plurality of elements may be a plane.

Element identifying module 926 may be configured to identify a first plurality of elements of the first plurality of images. Element identifying module 926 may be configured to identify a second plurality of elements of the second plurality of images. Identifying the first plurality of elements of the first plurality of images may include semantically segmenting each image of the first plurality of images. Identifying the first plurality of elements of the first plurality of images may further include labeling the semantically segmented first plurality of images. Identifying the second plurality of elements of the second plurality of images may include semantically segmenting each image of the second plurality of images. Identifying the second plurality of elements of the second plurality of elements may further include labeling the semantically segmented second plurality of elements. The first plurality of elements and the second plurality of elements may be associated with a building object. The first plurality of elements and the second plurality of elements may be associated with a structure of interest of the building object. The first plurality of elements and the second plurality of elements may be not associated with a building object. Element correlation module 928 may be configured to correlate the first plurality of elements with the second plurality of elements. Augmenting the first 3D model with the second 3D model may be based on the correlated plurality of elements.

Element identifying module 926 may be configured to identify a third plurality of elements. The third plurality of elements may include elements common to the first plurality of elements and the second plurality of elements. Augmenting the first 3D model with the second 3D model may be based on the third plurality of elements. The third plurality of elements may include elements common to the first plurality of elements and the second plurality of elements.

Aspect identifying module 930 may be configured to identify an aspect of an element of the first plurality of elements. Aspect identifying module 930 may be configured to identify a corresponding aspect of a corresponding element of the second plurality of elements. Augmenting the first 3D model with the second 3D model may include substantially aligning the aspect of the element of the first plurality of elements with the corresponding aspect of the corresponding element of the second plurality of elements. The aspect of the element of the first plurality of elements and the corresponding aspect of the corresponding element of the second plurality of elements may be a plane.

Augmenting the first 3D model with the second 3D model may include correlating the first 3D model with the second 3D model. Correlating the first 3D model with the second 3D model may include assigning a confidence value to each element of the first plurality of elements and the second plurality of elements. Assigning the confidence value to each element of the first plurality of elements and the second plurality of elements may be based on co-visibility of the first plurality of elements and the second plurality of elements. Assigning the confidence value to each element of the first plurality of elements and the second plurality of elements may be based on commonality of the first plurality of elements and the second plurality of elements.

Augmenting the first 3D model with the second 3D model may include offsetting the first 3D model from the second 3D model. Offsetting the first 3D model from the second 3D model may be based on one or more architectural elements. Offsetting the first 3D model from the second 3D model may be based on the matched architectural element. Offsetting the first 3D model from the second 3D model may be based on the matched architectural element. Offsetting the first 3D model from the second 3D model may be based on one or more values derived from one or more architectural elements. Offsetting the first 3D model from the second 3D model may be based on the derived value. Augmenting the first 3D model with the second 3D model may include dilating the first 3D model based on the second 3D model.

The first plurality of images may include a first plurality of anchor poses, wherein the second plurality of images includes a second plurality of anchor poses. Augmenting the first 3D model with the second 3D model may be based on anchor poses common to the first plurality of anchor poses and the second plurality of anchor poses.

Factor derivation module 932 may be configured to derive a scaling factor based on at least one of the first plurality of images, the second plurality of images, the first 3D model, a first coordinate system of the first 3D model, from the second 3D model, or a second coordinate system of the second 3D model. Image scaling module 934 may be configured to scale at least one of the first plurality of images, the second plurality of images, the first 3D model, a first coordinate system of the first 3D model, from the second 3D model, or a second coordinate system of the second 3D model based on the derived scale factor.

Subset selection module 936 may be configured to select a first subset of images of the first plurality of images based on at least one of translation data associated with the first plurality of images or rotation data associated with the first plurality of images. Generating the first 3D model may be based on the first subset of images. Subset selection module 936 may be configured to select a second subset of images of the second plurality of images based on at least one of translation data associated with the second plurality of images or rotation data associated with the second plurality of images. Generating the second 3D model may be based on the second subset of images.

Angular error calculation module 938 may be configured to calculate a first angular error of a first capture path associated with the first plurality of images. Rotation determination module 940 may be configured to determine a suggested rotation based on the first angular error of the first capture path. Rotation display module 942 may be configured to display the suggested rotation.

In some implementations, computing platform(s) 902, remote platform(s) 904, and/or external resources 944 may be operatively linked via one or more electronic communication links. For example, such electronic communication links may be established, at least in part, via a network such as the Internet and/or other networks. It will be appreciated that this is not intended to be limiting, and that the scope of this disclosure includes implementations in which computing platform(s) 902, remote platform(s) 904, and/or external resources 944 may be operatively linked via some other communication media.

A given remote platform 904 may include one or more processors configured to execute computer program modules. The computer program modules may be configured to enable an expert or user associated with the given remote platform 904 to interface with system 900 and/or external resources 944, and/or provide other functionality attributed herein to remote platform(s) 904. By way of non-limiting example, a given remote platform 904 and/or a given computing platform 902 may include one or more of a server, a desktop computer, a laptop computer, a handheld computer, a tablet computing platform, a NetBook, a Smartphone, a gaming console, and/or other computing platforms.

External resources 944 may include sources of information outside of system 900, external entities participating with system 900, and/or other resources. In some implementations, some or all of the functionality attributed herein to external resources 944 may be provided by resources included in system 900.

Computing platform(s) 902 may include electronic storage 946, one or more processors 948, and/or other components. Computing platform(s) 902 may include communication lines, or ports to enable the exchange of information with a network and/or other computing platforms. Illustration of computing platform(s) 902 in FIG. 9 is not intended to be limiting. Computing platform(s) 902 may include a plurality of hardware, software, and/or firmware components operating together to provide the functionality attributed herein to computing platform(s) 902. For example, computing platform(s) 902 may be implemented by a cloud of computing platforms operating together as computing platform(s) 902.

Electronic storage 946 may comprise non-transitory storage media that electronically stores information. The electronic storage media of electronic storage 946 may include one or both of system storage that is provided integrally (i.e., substantially non-removable) with computing platform(s) 902 and/or removable storage that is removably connectable to computing platform(s) 902 via, for example, a port (e.g., a USB port, a firewire port, etc.) or a drive (e.g., a disk drive, etc.). Electronic storage 946 may include one or more of optically readable storage media (e.g., optical disks, etc.), magnetically readable storage media (e.g., magnetic tape, magnetic hard drive, floppy drive, etc.), electrical charge-based storage media (e.g., EEPROM, RAM, etc.), solid-state storage media (e.g., flash drive, etc.), and/or other electronically readable storage media. Electronic storage 946 may include one or more virtual storage resources (e.g., cloud storage, a virtual private network, and/or other virtual storage resources). Electronic storage 946 may store software algorithms, information determined by processor(s) 948, information received from computing platform(s) 902, information received from remote platform(s) 904, and/or other information that enables computing platform(s) 902 to function as described herein.

Processor(s) 948 may be configured to provide information processing capabilities in computing platform(s) 902. As such, processor(s) 948 may include one or more of a digital processor, an analog processor, a digital circuit designed to process information, an analog circuit designed to process information, a state machine, and/or other mechanisms for electronically processing information. Although processor(s) 948 is shown in FIG. 9 as a single entity, this is for illustrative purposes only. In some implementations, processor(s) 948 may include a plurality of processing units. These processing units may be physically located within the same device, or processor(s) 948 may represent processing functionality of a plurality of devices operating in coordination. Processor(s) 948 may be configured to execute modules 908, 910, 912, 914, 916, 918, 920, 922, 924, 926, 928, 930, 932, 934, 936, 938, 940, and/or 942, and/or other modules. Processor(s) 948 may be configured to execute modules 908, 910, 912, 914, 916, 918, 920, 922, 924, 926, 928, 930, 932, 934, 936, 938, 940, and/or 942, and/or other modules by software; hardware; firmware; some combination of software, hardware, and/or firmware; and/or other mechanisms for configuring processing capabilities on processor(s) 948. As used herein, the term “module” may refer to any component or set of components that perform the functionality attributed to the module. This may include one or more physical processors during execution of processor readable instructions, the processor readable instructions, circuitry, hardware, storage media, or any other components.

It should be appreciated that although modules 908, 910, 912, 914, 916, 918, 920, 922, 924, 926, 928, 930, 932, 934, 936, 938, 940, and/or 942 are illustrated in FIG. 9 as being implemented within a single processing unit, in implementations in which processor(s) 948 includes multiple processing units, one or more of modules 908, 910, 912, 914, 916, 918, 920, 922, 924, 926, 928, 930, 932, 934, 936, 938, 940, and/or 942 may be implemented remotely from the other modules. The description of the functionality provided by the different modules 908, 910, 912, 914, 916, 918, 920, 922, 924, 926, 928, 930, 932, 934, 936, 938, 940, and/or 942 described below is for illustrative purposes, and is not intended to be limiting, as any of modules 908, 910, 912, 914, 916, 918, 920, 922, 924, 926, 928, 930, 932, 934, 936, 938, 940, and/or 942 may provide more or less functionality than is described. For example, one or more of modules 908, 910, 912, 914, 916, 918, 920, 922, 924, 926, 928, 930, 932, 934, 936, 938, 940, and/or 942 may be eliminated, and some or all of its functionality may be provided by other ones of modules 908, 910, 912, 914, 916, 918, 920, 922, 924, 926, 928, 930, 932, 934, 936, 938, 940, and/or 942. As another example, processor(s) 948 may be configured to execute one or more additional modules that may perform some or all of the functionality attributed below to one of modules 908, 910, 912, 914, 916, 918, 920, 922, 924, 926, 928, 930, 932, 934, 936, 938, 940, and/or 942.

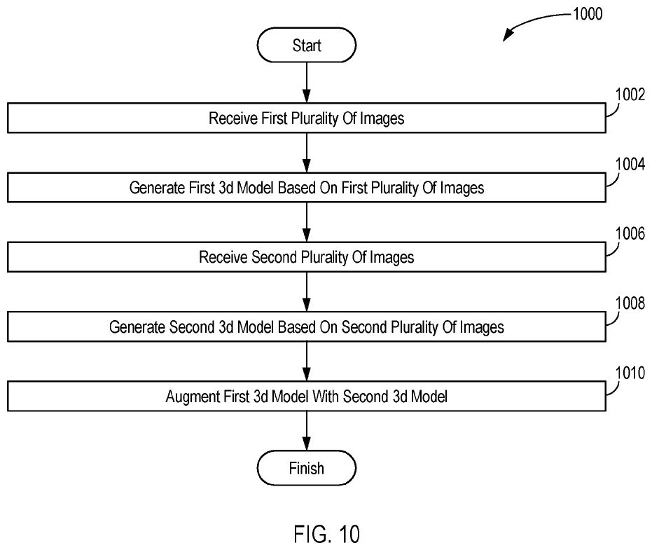

FIG. 10 illustrates a method 1000 for augmenting 3D models, in accordance with one or more implementations. The operations of method 1000 presented below are intended to be illustrative. In some implementations, method 1000 may be accomplished with one or more additional operations not described, and/or without one or more of the operations discussed. Additionally, the order in which the operations of method 1000 are illustrated in FIG. 10 and described below is not intended to be limiting.

In some implementations, method 1000 may be implemented in one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 1000 in response to instructions stored electronically on an electronic storage medium. The one or more processing devices may include one or more devices configured through hardware, firmware, and/or software to be specifically designed for execution of one or more of the operations of method 1000.

An operation 1002 may include receiving a first plurality of images. Operation 1002 may be performed by one or more hardware processors configured by machine-readable instructions including a module that is the same as or similar to image receiving module 908, in accordance with one or more implementations.

An operation 1004 may include generating a first 3D model based on the first plurality of images. Operation 1004 may be performed by one or more hardware processors configured by machine-readable instructions including a module that is the same as or similar to model generating module 910, in accordance with one or more implementations.

An operation 1006 may include receiving a second plurality of images. Operation 1006 may be performed by one or more hardware processors configured by machine-readable instructions including a module that is the same as or similar to image receiving module 908, in accordance with one or more implementations.

An operation 1008 may include generating a second 3D model based on the second plurality of images. Operation 1008 may be performed by one or more hardware processors configured by machine-readable instructions including a module that is the same as or similar to model generating module 910, in accordance with one or more implementations.

An operation 1010 may include augmenting the first 3D model with the second 3D model. Operation 1010 may be performed by one or more hardware processors configured by machine-readable instructions including a module that is the same as or similar to model augmentation module 912, in accordance with one or more implementations.

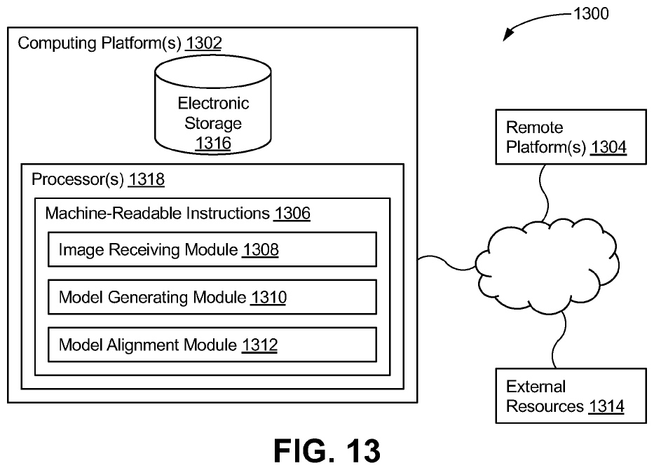

FIG. 13 illustrates a system 1300 configured for combining disparate 3d models of a common building object, in accordance with one or more implementations. In some implementations, system 1300 may include one or more computing platforms 1302. Computing platform(s) 1302 may be configured to communicate with one or more remote platforms 1304 according to a client/server architecture, a peer-to-peer architecture, and/or other architectures. Remote platform(s) 1304 may be configured to communicate with other remote platforms via computing platform(s) 1302 and/or according to a client/server architecture, a peer-to-peer architecture, and/or other architectures. Users may access system 1300 via remote platform(s) 1304.

Computing platform(s) 1302 may be configured with machine-readable instructions 1306. Machine-readable instructions 1306 may include one or more instruction modules. The instruction modules may include computer program modules. The instruction modules may include one or more of image receiving module 1308, model generating module 1310, model alignment module 1312, and/or other instruction modules.

Image receiving module 1308 may be configured to receive a first plurality of images.

Image receiving module 1308 may be configured to receive a second plurality of images.

Model generating module 1310 may be configured to generate a first 3d model based on the first plurality of images. The first 3d model may be an interior model of the building object.

Model generating module 1310 may be configured to generate a second 3d model based on the second plurality of images. The second 3d model may be an exterior model of the building object.

Model alignment module 1312 may be configured to align, in a common 3d coordinate system, the first 3d model with the second 3d model.

In some implementations, computing platform(s) 1302, remote platform(s) 1304, and/or external resources 1314 may be operatively linked via one or more electronic communication links. For example, such electronic communication links may be established, at least in part, via a network such as the Internet and/or other networks. It will be appreciated that this is not intended to be limiting, and that the scope of this disclosure includes implementations in which computing platform(s) 1302, remote platform(s) 1304, and/or external resources 1314 may be operatively linked via some other communication media.

A given remote platform 1304 may include one or more processors configured to execute computer program modules. The computer program modules may be configured to enable an expert or user associated with the given remote platform 1304 to interface with system 1300 and/or external resources 1314, and/or provide other functionality attributed herein to remote platform(s) 1304. By way of non-limiting example, a given remote platform 1304 and/or a given computing platform 1302 may include one or more of a server, a desktop computer, a laptop computer, a handheld computer, a tablet computing platform, a NetBook, a Smartphone, a gaming console, and/or other computing platforms.

External resources 1314 may include sources of information outside of system 1300, external entities participating with system 1300, and/or other resources. In some implementations, some or all of the functionality attributed herein to external resources 1314 may be provided by resources included in system 1300.

Computing platform(s) 1302 may include electronic storage 1316, one or more processors 1318, and/or other components. Computing platform(s) 1302 may include communication lines, or ports to enable the exchange of information with a network and/or other computing platforms. Illustration of computing platform(s) 1302 in FIG. 13 is not intended to be limiting. Computing platform(s) 1302 may include a plurality of hardware, software, and/or firmware components operating together to provide the functionality attributed herein to computing platform(s) 1302. For example, computing platform(s) 1302 may be implemented by a cloud of computing platforms operating together as computing platform(s) 1302.

Electronic storage 1316 may comprise non-transitory storage media that electronically stores information. The electronic storage media of electronic storage 1316 may include one or both of system storage that is provided integrally (i.e., substantially non-removable) with computing platform(s) 1302 and/or removable storage that is removably connectable to computing platform(s) 1302 via, for example, a port (e.g., a USB port, a firewire port, etc.) or a drive (e.g., a disk drive, etc.). Electronic storage 1316 may include one or more of optically readable storage media (e.g., optical disks, etc.), magnetically readable storage media (e.g., magnetic tape, magnetic hard drive, floppy drive, etc.), electrical charge-based storage media (e.g., EEPROM, RAM, etc.), solid-state storage media (e.g., flash drive, etc.), and/or other electronically readable storage media. Electronic storage 1316 may include one or more virtual storage resources (e.g., cloud storage, a virtual private network, and/or other virtual storage resources). Electronic storage 1316 may store software algorithms, information determined by processor(s) 1318, information received from computing platform(s) 1302, information received from remote platform(s) 1304, and/or other information that enables computing platform(s) 1302 to function as described herein.

Processor(s) 1318 may be configured to provide information processing capabilities in computing platform(s) 1302. As such, processor(s) 1318 may include one or more of a digital processor, an analog processor, a digital circuit designed to process information, an analog circuit designed to process information, a state machine, and/or other mechanisms for electronically processing information. Although processor(s) 1318 is shown in FIG. 13 as a single entity, this is for illustrative purposes only. In some implementations, processor(s) 1318 may include a plurality of processing units. These processing units may be physically located within the same device, or processor(s) 1318 may represent processing functionality of a plurality of devices operating in coordination. Processor(s) 1318 may be configured to execute modules 1308, 1310, and/or 1312, and/or other modules. Processor(s) 1318 may be configured to execute modules 1308, 1310, and/or 1312, and/or other modules by software; hardware; firmware; some combination of software, hardware, and/or firmware; and/or other mechanisms for configuring processing capabilities on processor(s) 1318. As used herein, the term “module” may refer to any component or set of components that perform the functionality attributed to the module. This may include one or more physical processors during execution of processor readable instructions, the processor readable instructions, circuitry, hardware, storage media, or any other components.

It should be appreciated that although modules 1308, 1310, and/or 1312 are illustrated in FIG. 13 as being implemented within a single processing unit, in implementations in which processor(s) 1318 includes multiple processing units, one or more of modules 1308, 1310, and/or 1312 may be implemented remotely from the other modules. The description of the functionality provided by the different modules 1308, 1310, and/or 1312 described below is for illustrative purposes, and is not intended to be limiting, as any of modules 1308, 1310, and/or 1312 may provide more or less functionality than is described. For example, one or more of modules 1308, 1310, and/or 1312 may be eliminated, and some or all of its functionality may be provided by other ones of modules 1308, 1310, and/or 1312. As another example, processor(s) 1318 may be configured to execute one or more additional modules that may perform some or all of the functionality attributed below to one of modules 1308, 1310, and/or 1312.

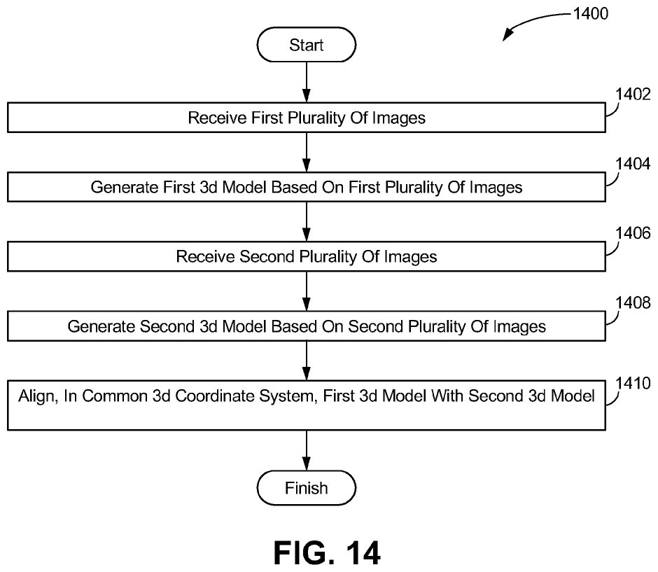

FIG. 14 illustrates a method 1400 for combining disparate 3d models of a common building object, in accordance with one or more implementations. The operations of method 1400 presented below are intended to be illustrative. In some implementations, method 1400 may be accomplished with one or more additional operations not described, and/or without one or more of the operations discussed. Additionally, the order in which the operations of method 1400 are illustrated in FIG. 14 and described below is not intended to be limiting.

In some implementations, method 1400 may be implemented in one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 1400 in response to instructions stored electronically on an electronic storage medium. The one or more processing devices may include one or more devices configured through hardware, firmware, and/or software to be specifically designed for execution of one or more of the operations of method 1400.

An operation 1402 may include receiving a first plurality of images. The first plurality of images may include at least one of visual data or depth data. Visual data may include at least one of image data or video data, and depth data may include at least one of point clouds, line clouds, meshes, or points. The first plurality of images may be captured by one or more of a smartphone, a tablet computer, an augmented reality headset, a virtual reality headset, a drone, and an aerial platform. The first plurality of images may include an interior of the building object. Operation 1402 may be performed by one or more hardware processors configured with machine-readable instructions including a module that is the same as or similar to image receiving module 1308, in accordance with one or more implementations.

An operation 1404 may include generating a first 3d model based on the first plurality of images. The first 3d model may be an interior model of the building object. The first 3d model may include at least one of a polygon-based model or a primitive-based model. The first 3d model may include an interior of the building model. The first 3d model may be at least one of a point cloud, line cloud, or mesh model. Operation 1404 may be performed by one or more hardware processors configured with machine-readable instructions including a module that is the same as or similar to model generating module 1310, in accordance with one or more implementations.

An operation 1406 may include receiving a second plurality of images. The second plurality of images may include at least one of visual data or depth data. Visual data may include at least one of image data or video data, and depth data may include at least one of point clouds, line clouds, meshes, or points. The second plurality of images may be captured by one or more of a smartphone, a tablet computer, an augmented reality headset, a virtual reality headset, a drone, and an aerial platform. The second plurality of images may include an exterior of the building object. Operation 1406 may be performed by one or more hardware processors configured with machine-readable instructions including a module that is the same as or similar to image receiving module 1308, in accordance with one or more implementations.

A first subset of images of the first plurality of images may be selected based on at least one of translation data associated with the first plurality of images, rotation data associated with the first plurality of images, camera frustum orientation data associated with the first plurality of images, or a combination thereof. The first 3D model may be generated based on the first subset of images. A second subset of images of the second plurality of images may be selected based on at least one of translation data associated with the second plurality of images, rotation data associated with the second plurality of images, camera frustum orientation data associated with the second plurality of images, or a combination thereof. The second 3D model may be generated based on the second subset of images. The first subset of images and the second subset of images may have sufficiently similar camera information, such as translation data, rotation data, camera frustum orientation data, or a combination thereof, or visual information, such as image data.

For example, translation data, rotation data, camera frustum orientation data, or a combination thereof, associated with a plurality of interior images may be inside of a building object facing outward and translation data, rotation data, camera frustum orientation data, or a combination thereof, associated with a plurality of exterior images may be outside of the building object facing inward. In this example, a subset of the plurality of interior images and a corresponding subset of the plurality of exterior images may be selected such that the translation data, rotation data, camera frustum orientation data, or a combination thereof, that correspond to the same portions of the building object may be used to generate the interior model and the exterior model. In this example the subset of the plurality of interior images and the corresponding subset of the plurality of exterior images may have sufficiently similar camera information, such as translation data, rotation data, camera frustum orientation data, or a combination thereof, or visual information, such as image data.

A first subset of images of the first plurality of images may be selected based on at least one of translation data associated with the first plurality of images, rotation data associated with the first plurality of images, camera frustum orientation data associated with the first plurality of images, or a combination thereof. A second subset of images of the second plurality of images may be selected based on at least one of translation data associated with the second plurality of images, rotation data associated with the second plurality of images, camera frustum orientation data associated with the second plurality of images, or a combination thereof. A single 3d model may be generated based on the first subset of images and the second subset of images. The first subset of images and the second subset of images may have sufficiently similar camera information, such as translation data, rotation data, camera frustum orientation data, or a combination thereof, or visual information, such as image data.

For example, translation data, rotation data, camera frustum orientation data, or a combination thereof, associated with a plurality of interior images may be inside of a building object facing outward and translation data, rotation data, camera frustum orientation data, or a combination thereof, associated with a plurality of exterior images may be outside of the building object facing inward. In this example, a subset of the plurality of interior images and a corresponding subset of the plurality of exterior images may be selected such that the translation data, rotation data, camera frustum orientation data, or a combination thereof, that correspond to the same portions of the building object may be used to a single model of the interior and exterior of the building object. In this example the subset of the plurality of interior images and the corresponding subset of the plurality of exterior images may have sufficiently similar camera information, such as translation data, rotation data, camera frustum orientation data, or a combination thereof, or visual information, such as image data.

An operation 1408 may include generating a second 3d model based on the second plurality of images. The second 3d model may be an exterior model of the building object. The second 3d model may include at least one of a polygon-based model or a primitive-based model. The second 3d model may include an exterior of the building model. The second 3d model may be at least one of a point cloud, line cloud, or mesh model. Operation 1408 may be performed by one or more hardware processors configured with machine-readable instructions including a module that is the same as or similar to model generating module 1310, in accordance with one or more implementations.

An operation 1410 may include aligning, in a common 3d coordinate system, the first 3d model with the second 3d model. In some embodiments, the aligning is with respect to a coordinate system of either the first 3d model or the second 3d model. In some examples, aligning the first 3d model with the second 3d model may be according to a coordinate system of the first 3d model. In these examples, the common 3d coordinate system is the coordinate system of the first 3d model. In these examples, aligning the first 3d model with the second 3d model may result in a modified version first 3d model that includes the second 3d model. In some examples, aligning the first 3d model with the second 3d model may be according to a coordinate system of the second 3d model. In these examples, the common 3d coordinate system is the coordinate system of the second 3d model. In these examples, aligning the first 3d model with the second 3d model may result in a modified version of the second 3d model that includes the first 3d model. In some examples, the aligning is with respect to a coordinate system that is separate from a coordinate system the first 3d model and a coordinate system of the second 3d model. In these examples, the coordinate system may be created, for example based on the coordinate system of the first 3d model, the coordinate of the second 3d model, the first 3d model, the second 3d model, or a combination thereof. Each of the first 3d model and the second 3d model may be transformed according to the coordinate system. In these examples, aligning the first 3d model with the second 3d model may result in a new model that is separate from the first 3d model and the second 3d model. Operation 1410 may be performed by one or more hardware processors configured with machine-readable instructions including a module that is the same as or similar to model alignment module 1312, in accordance with one or more implementations.

Aligning the first 3D model with the second 3D model is based on location information. In some examples, the location information may be associated with the first 3D model and the second 3D model. In some examples, the location information may be associated with the first plurality of images and the second plurality of images. The location information may include latitude and longitude information. The location information may include, or be derived from, relative locations of first cameras associated with the first plurality of images and of second cameras associated with the second plurality of images.

The common 3d coordinate system may be generated. The first 3d model may be associated with a first coordinate system and the second 3d model may be associated with a second coordinate system. The common 3d coordinate system may be generated based on the first coordinate system and the second coordinate system. In some examples, generating the common 3d coordinate system may include matching the first coordinate system with the second coordinate system. In some examples, generating the common 3d coordinate system may include aligning first axes of the first 3D model with second axes of the second 3D model. In some embodiments, the first coordinate system may include the first axes and the second coordinate system may include the second axes. In some embodiments, the first axes of the first 3d model may be a first origin of the first 3d model and the second axes of the second 3d model may be a second origin of the second 3d model. The first origin and the second origin may be origins of Manhattan axes systems. In some embodiments, the first axes of the first 3d model may be first dominant axes of the first 3d model and the second axes of the second 3d model may be second dominant axes of the second 3d model. The first dominant axes and the second dominant axes may be axes of Manhattan axes system. Dominant axes are related to the model, include three axes such as d₁, d₂, d₃, where a first axis is vertical, a second axis is defined by a longest direction of the model, for example determined by line segment orientation, and a third axis is orthogonal to the first axis and the second axis. Aligning first axes of the first 3D model with second axes of the second 3D model may be based on one or more geometric constraints. In some embodiments, the first 3d model and the second 3d model may include piece-wise planar surfaces with dominant directions. The piece-wise planar surfaces are a plurality of planar surfaces, and a dominant direction of a planar surface is the direction of the normal of the planar surface. In these embodiments, the one or more geometric constraints may be based on the piece-wise planar surfaces.

A first plurality of sides of the first 3d model and a second plurality of sides of the second 3d model may be identified. Each side of the first plurality of sides and the second plurality of sides may correspond to a side of the building object, such a facade. Aligning the first 3d model with the second 3d model may include aligning the first plurality of sides with the second plurality of sides in the common 3d coordinate system such that the first plurality of sides are within a threshold number of 3d pixels of the second plurality of sides. The threshold number of pixels may be associated with industry standard values for the building object, such as wall thickness values. The industry standard values may depend on a variety of parameters such as, for example, building object type (e.g., residential, commercial, etc.) framing material, exterior finishes, and the like. The parameters may be determined from the images, for example through semantic segmentation and labeling. The threshold number of 3d pixels may be 15 pixels. The first plurality of sides and the second plurality of sides may be planar surfaces. Aligning the first 3d model with the second 3d model may be based on surface normal of the planar surfaces. A first side of the first plurality of sides may be aligned with a corresponding first side of the second plurality of sides such that a surface normal of the first side of the plurality of first sides is within a threshold number of degrees of a surface normal of the corresponding first side of the second plurality of sides. The threshold number of degrees may be five degrees. This may be repeated for each side of the first plurality of sides and corresponding side of the second plurality of sides. The first plurality of sides and the second plurality of sides may be substantially aligned when alignment of surface normals of the first plurality of sides produces alignment of surface normals of the second plurality of sides. For example, a front side of an interior model may be aligned with a corresponding front side of an exterior model such that a surface normal of the front side of the interior model is within five degrees of a surface normal of the front side of the exterior model.

Aligning the first 3d model with the second 3d model may be based on a first outline of the first 3d model and a second outline of the second 3d model. The first outline may be generated, for example based on a top-down view of the first 3d model, and the second outline may be generated, for example based on a top-down view of the second 3d model. The first outline and the second outline may be two-dimensional (2d), for example a floorplan. Aligning the first 3d model with the second 3d model may include aligning the first outline with the second outline such that the first outline is within a threshold number of pixels of the second outline. The threshold number of pixels may be associated with industry standard values for the building object, such as wall thickness values. The industry standard values may depend on a variety of parameters such as, for example, building object type (e.g., residential, commercial, etc.) framing material, exterior finishes, and the like. The parameters may be determined from the images, for example through semantic segmentation and labeling. The threshold number of pixels may be 15 pixels. The threshold number may be in real units such as feet or meters. The threshold number of real units may be 0.5 feet. For example, an interior floorplan generated based on a top-down view of an interior model may be aligned with an exterior floorplan generated based on a top-down view of an exterior model such that the interior floorplan is within 15 pixels of the exterior floorplan. In some examples, a perimeter or envelope of the interior floorplan may be within 15 pixels of a perimeter or envelope of the exterior floorplan. In some examples, a perimeter or envelope of the interior floor plan may be within 0.5 feet of a perimeter or envelope of the exterior floor plan.

Aligning the first outline with the second outline may be based on one or more architectural elements, for example walls, doors, windows, and the like. An architectural element of the first 3d model, the first plurality of images, or a combination thereof, may be matched with a corresponding architectural element of the second 3d model, the second plurality of images, or a combination thereof, and aligning the first outline with the second outline may be based on the matched architectural element. For example, a door of an interior model, plurality of interior images, or a combination thereof, may be matched with a corresponding door of an exterior model, plurality of exterior images, or a combination thereof, and aligning an interior floorplan with an exterior floorplan may be based on the matched door.

Aligning the first outline with the second outline may be based on one or more values derived from one or more architectural elements, for example walls, doors, windows, and the like. An architectural element of the first 3d model, the first plurality of images, or a combination thereof, may be matched with a corresponding architectural element of the second 3d model, the second plurality of images, or a combination thereof. Aligning the first 3d model with the second 3d model may be based on the matched architectural element. A value may be derived based on the alignment of the first 3d model with the second 3d model. Aligning the first outline with the second outline is based on the derived value. For example, a door of an interior model, a plurality of interior images, or a combination thereof, may be matched with a corresponding door of an exterior model, a plurality of exterior images, or a combination thereof. Aligning the interior model with the exterior model may be based on the matched door. A value, such as a depth of the door, may be derived based on the alignment of the interior model with the exterior model. Aligning an interior floorplan with an exterior floorplan may be based on the depth of the door. The interior floorplan and the exterior floorplan are offset from one another by the depth of the door.

A first plurality of sides of the first outline may be identified and a second plurality of sides of the second outline may be identified. Each side of the first plurality of sides and the second plurality of sides may correspond to a side of the building object, such as a facade. The first plurality of sides may correspond to interior sides of the building object and the second plurality of sides may correspond to exterior sides of the building object. Aligning the first 3d model with the second 3d model may include aligning the first plurality of sides with the second plurality of sides in a common 3d coordinate system such that the first plurality of sides are within a threshold number of pixels of the second plurality of sides. The threshold number of 3d pixels may be associated with industry standard values for the building object, such as wall thickness values. The industry standard values may depend on a variety of parameters such as, for example, building object type (e.g., residential, commercial, etc.) framing material, exterior finishes, and the like. The parameters may be determined from the images, for example through semantic segmentation and labeling. The threshold number of pixels may be 15 pixels. The first plurality of sides and the second plurality of sides may be planar surfaces. Aligning the first 3d model with the second 3d model may be based on surface normals of the first plurality of sides and the second plurality of sides. Aligning the first 3d model with the second 3d model may include aligning a first side of the first plurality of sides with a corresponding first side of the second plurality of sides such that a surface normal of the first side of the first plurality of sides is within a threshold number of degrees of a surface normal of the corresponding first side of the second plurality of sides. The threshold number of degrees may be five degrees. The first plurality of sides and the second plurality of sides may be substantially aligned when alignment of surface normals of the first plurality of sides produces alignment of surface normals of the second plurality of sides. For example, a first plurality of sides of an interior floorplan may be identified and a second plurality of sides of an exterior floorplan may be identified. The first plurality of sides may correspond to interior sides of the building object and the second plurality of sides may correspond to exterior sides of the building object. Aligning an interior model with an exterior model may include aligning the interior sides with the exterior sides in a common 3d coordinate system such that the interior sides are within a threshold number of pixels of the exterior sides. The interior sides and the exterior sides may be planar surfaces. Aligning the interior model with the exterior model may be based on surface normals of the interior sides and the exterior sides. Aligning the interior model with the exterior model may include aligning a first side of the interior sides with a corresponding first side of the exterior sides such that a surface normal of the first side of the interior sides is within a threshold number of degrees of a surface normal of the corresponding first side of the exterior sides.

A first plurality of elements of the first 3d model, the first plurality of images, or a combination thereof, and a second plurality of elements of the second 3d model, the second plurality of images, or a combination thereof may be identified. Examples of elements include architectural elements and non-architectural elements. Examples of architectural elements include walls, doors, windows, and the like. Examples of non-architectural elements include vehicles (e.g., cars, motorcycles, bikes, boats, etc.), landscaping (e.g., trees, bushes, etc.), and the like. The first plurality of elements and the second plurality of elements may be associated with the building object, for example a structure of interest of the building object. Examples of elements associated with a building object include architectural elements. The first plurality of elements and the second plurality of elements may not be associated with the building object. Examples of elements not associated with a building object include non-architectural elements. Identifying the first plurality of elements may include semantically segmenting and labeling the first 3d model, the first plurality of images, or a combination thereof, and identifying the second plurality of elements may include semantically segmenting and labeling the second 3d model, the second plurality of images, or a combination thereof. For example, an interior model, a plurality of interior images, or a combination thereof, and an exterior 3d model, a plurality of exterior images, or a combination thereof may be semantically segmented and labeled by architectural elements, non-architectural elements, or a combination thereof, or aspects/portions thereof.

The first plurality of elements may be correlated with the second plurality of elements. Aligning the first 3d model with the second 3d model may be based on the correlated elements. For example, doors of a first plurality of elements may be correlated with doors of a second plurality of elements, and aligning an interior model with an exterior model may be based on the correlated doors. A third plurality of elements may be identified, where the third plurality of elements includes elements common to the first plurality of elements and the second plurality of elements. Aligning the first 3d model with the second 3d model may be based on the third plurality of elements. For example, a third plurality of elements including doors may be identified, where the doors of the third plurality of elements are doors common to a first plurality of elements and a second plurality of elements, and aligning an interior model with an exterior model may be based on the doors of the third plurality of elements. Identifying the common elements may be based on camera frustum orientations associated with the first and second plurality of images. For example, camera frustum orientations associated with a plurality of interior images may be inside of the building object facing outward and camera frustums associated with a plurality of exterior images may be outside of the building object facing inward. In this example, aligning an interior model with an exterior model may be based on locations of the camera frustums, for example relative to one another, the building object, or a combination thereof. For example, camera frustums associated with the plurality of interior images and the plurality of exterior images that observe same portions of the building object may be used for aligning an interior model with an exterior model. Aligning the first 3d model with the second 3d model may include transforming the first 3d model into a coordinate space of the second 3d model such that the first 3d model and the second 3d model substantially align at the third plurality of elements. In some embodiments, substantially aligning may include not only aligning the third plurality of elements, but also aligning at least one other element. For example, an interior model may be transformed into a coordinate space of an exterior model such that the interior model and the exterior model substantially align at doors of a third plurality of elements. In this example, substantially aligning may include not only aligning the doors of the third plurality of elements, but also aligning at least one other element such as windows.

An aspect of an element of the first plurality of elements may be identified, a corresponding aspect of a corresponding element of the second plurality of elements may be identified, and aligning the first 3d model with the second 3d model may include aligning the aspect of the element of the first plurality of elements with the corresponding aspect of the corresponding element of the second plurality of elements. The aspect of the element of the first plurality of elements and the corresponding aspect of the corresponding element of the second plurality of elements may be a plane, line segment, or the like. For example, a top of a door of a first plurality of elements may be identified, a corresponding top of a corresponding door of a second plurality of elements may be identified, and aligning an interior model with an exterior model may include aligning the top of the door of the first plurality of elements with the corresponding top of the corresponding door of the second plurality of elements.

Aligning the first 3d model with the second 3d model may include correlating the first 3d model with the second 3d model. A first plurality of elements of the first 3d model, the first plurality of images, or a combination thereof may be identified and a second plurality of elements of the second 3d model, the second plurality of images, or a combination thereof may be identified. Examples of elements include architectural elements and non-architectural elements. Examples of architectural elements include walls, doors, windows, and the like. Examples of non-architectural elements include vehicles (e.g., cars, motorcycles, bikes, boats, etc.), landscaping (e.g., trees, bushes, etc.), and the like. Correlating the first 3d model with the second 3d model may include assigning a confidence value to each element of the first plurality of elements and the second plurality of elements. Assigning the confidence value may be based on co-visibility, commonality, or both, of the first plurality of elements and the second plurality of elements. A confidence value may be a numerical representation of a measure or probability an element of the first plurality of elements is visible by, sees, matches, or a combination thereof, an element of the second plurality of elements. Correlating the first 3d model with the second 3d model may include correlating on the first plurality of elements with the second plurality of elements.

Aligning the first 3d model with the second 3d model may be based on one or more architectural elements, one or more non-architectural elements, or a combination thereof. The one or more architectural elements may include walls, doors, windows, and the like. The one or more non-architectural elements may include vehicles (e.g., cars, motorcycles, bicycles, boats, etc.), landscaping (e.g., trees, bushes, etc.), light poles, fire hydrants, and the like. An architectural, or non-architectural, element of the first 3d model may be matched with a corresponding architectural, or non-architectural, element of the second model. Aligning the first 3d model with the second 3d model may be based on the matched architectural, or non-architectural, element. For example, a door of an interior model may be matched with a corresponding door of an exterior model. In this example, the interior model may be aligned with the exterior model based on the matched door. An architectural, or non-architectural, element of the first plurality of images may be matched with a corresponding architectural, or non-architectural, element of the second plurality of images. Aligning the first 3d model with the second 3d model may be based on the matched architectural, or non-architectural element. For example, a car of a plurality of interior images may be matched with a corresponding car of a plurality of exterior images. In this example, an interior model may be aligned with an exterior model based on the matched car. The car of the plurality of interior images may be seen through doors or windows of the building object and the car of the plurality of exterior images may be seen around the building object.

Aligning the first 3d model with the second 3d model may be based on one or more values derived from one or more architectural elements, one or more non-architectural elements, or a combination thereof. Examples of values include dimension such as length, area, volume, scaling factor, and the like. An architectural, or non-architectural, element of the first 3d model may be matched with a corresponding architectural, or non-architectural, element of the second 3d model. Aligning the first 3d model with the second 3d model may be based on the matched architectural, or non-architectural, element. A value may be derived based on the alignment of the first 3d model with the second 3d model. The first 3d model may be realigned with the second 3d model based on the derived value. An architectural, or non-architectural, element of the first plurality of images may be matched with a corresponding architectural, or non-architectural, element of the second plurality of images. Aligning the first 3d model with the second 3d model may be based on the matched architectural, or non-architectural, element. A value may be derived based on the alignment of the first 3d model with the second 3d model. The first 3d model may be realigned with the second 3d model based on the derived value.

Aligning the first 3d model with the second 3d model may include one or more of dilating, contracting, or scaling the first 3d model based on the second 3d model, or vice versa. A scaling factor may be derived based on at least one of the first plurality of images, the second plurality of images, the first 3d model, a first coordinate system of the first 3d model, from the second 3d model, or a second coordinate system of the second 3d model. The first plurality of images, the second plurality of images, the first 3d model, a first coordinate system of the first 3d model, from the second 3d model, or a second coordinate system of the second 3d model may be scaled based on the derived scaling factor.

The first plurality of images may include a first plurality of anchor poses and the second plurality of images may include a second plurality of anchor poses. Aligning the first 3d model with the second 3d model may be based on anchor poses common to the first plurality of anchor poses and the second plurality of anchor poses. Anchor poses may describe positions and orientations of real or virtual objects relative to cameras that captured the images.

A first angular error of a first capture path associated with the first plurality of images may be calculated, for example during capture of the first plurality of images. A suggested rotation may be determined based on the first angular error of the first capture path. The suggested rotation may be displayed, for example on a display of a device capturing the first plurality of images. A second angular error of a second capture path associated with the second plurality of images may be calculated, for example during capture of the second plurality of images. A suggested rotation may be determined based on the second angular error of the second capture path. The suggested rotation may be displayed, for example on a display of a device capturing the first plurality of images.

The first plurality of images may be associated with a first plurality of camera poses, and the second plurality of images may be associated with a second plurality of camera poses. Aligning the first 3d model with the second 3d model may be based on relative locations of the first plurality of camera poses and the second plurality of camera poses. Aligning the first 3d model with the second 3d model may be based on relative locations of the first plurality of images and the second plurality of images. The first plurality of camera poses may be associated with a first capture path, and the second plurality of camera poses may be associated with a second capture path. Aligning the first 3d model with the second 3d model may be based on relative locations of the first capture path and the second capture path. For example, a plurality of interior images, interior camera poses, and an interior capture path may be inside of the building object and a plurality of exterior images, exterior camera poses, and an exterior capture path may be outside of the building object. In this example, aligning an interior model with an exterior model may be based on locations of the images, camera poses, and capture paths, for example relative to one another, the building object, or a combination thereof.

The first plurality of images may be associated with a first plurality of camera frustums, and the second plurality of images may be associated with a second plurality of camera frustums. Aligning the first 3d model with the second 3d model may be based on relative locations of the first plurality of camera frustums and the second plurality of camera frustums. For example, one or more of a plurality of interior camera frustums may be inside of the building object facing outward and one or more of a plurality of exterior camera frustums may be outside of the building object facing inward. In this example, aligning an interior model with an exterior model may be based on locations of the camera frustums, for example relative to one another, the building object, or a combination thereof. For example, camera frustums of the plurality of interior camera frustums and camera frustums of the plurality of exterior camera frustums that observe same portions of the building object may be used for aligning the interior model with the exterior model.

Aligning the first 3d model with the second 3d model may be based on a third model. The third model may be a 2d model or a 3d model. The third model may be generated based on at least one of a blueprint, a floorplan, or a third plurality of images. The third model may be generated based on the first 3d model and the second 3d model. The third model may be generated based on the first plurality of images and the second plurality of images.

Aligning the first 3d model with the second 3d model may include reconstructing the first 3d model based on the second 3d model. Reconstructing may include generating new geometries of the first 3d model based on the second 3d model. Generating the new geometries may be according to the common 3d coordinate system. For example, if an interior model is of a front portion of the building object and an exterior model is of front and back portions of the building object, the interior model may be reconstructed by generating new geometries that correspond to back portions of the building object based on the exterior model.

Aligning the first 3d model with the second 3d model may include reconstructing the second 3d model based on the first 3d model. Reconstructing may include generating new geometries of the second 3d model based on the first 3d model. Generating the new geometries may be according to the common 3d coordinate system. For example, if an exterior model is of a front portion of the building object and an interior model is of front and back portions of the building object, the exterior model may be reconstructed by generating new geometries that correspond to back portions of the building object based on the interior model.

Aligning the first 3d model with the second 3d model may include reconstructing the first 3d model based on the second 3d model, and reconstructing the second 3d model based on the first 3d model. Reconstructing the first 3d model based on the second 3d model may include generating new geometries of the first 3d model based on the second 3d model. Reconstructing the second 3d model based on the first 3d model may include generating new geometries of the second 3d model based on the first 3d model. Generating the new geometries may be according to the common 3d coordinate system. For example, if an interior model is of a front portion of the building object and an exterior model is of a back portion of the building object, the interior model may be reconstructed by generating new geometries that correspond to back portions of the building object based on the exterior model, and the exterior model may be reconstructed by generating new geometries that correspond to front portions of the building model based on the interior model.

In some embodiments, the method 1400 includes representing the first 3d model and the second 3d model in a coordinate space of the first 3d model. In some embodiments, the method 1400 includes representing the first 3d model and the second 3d model in a coordinate space of the second 3d model. In some embodiments, the method includes representing the first 3d model and the second 3d model in a coordinate space of a new model, where the new model is generated from the first plurality of images, the first 3d model, the second plurality of images, the second 3d model, or a combination thereof.

In some embodiments, the method 1400 includes modifying the models. In some examples, the method 1400 may include modifying the first 3d model based on the second 3d model in a coordinate space of the first 3d model. In some examples, the method 1400 may include modifying the second 3d model with the first 3d model in a coordinate space of the second 3d model. In some examples, the method 1400 includes modifying the first 3d model and the second 3d model based on a coordinate space of a new model, where the new model is generated from the first plurality of images, the first 3d model, the second plurality of images, the second 3d model, or a combination thereof. Modifying may include adding geometries (e.g., filing in), removing geometries, moving geometries, scaling geometries, and the like.

All of the processes described herein may be embodied in, and fully automated, via software code modules executed by a computing system that includes one or more computers or processors. The code modules may be stored in any type of non-transitory computer-readable medium or other computer storage device. Some or all the methods may be embodied in specialized computer hardware.

Many other variations than those described herein will be apparent from this disclosure. For example, depending on the embodiment, certain acts, events, or functions of any of the algorithms described herein can be performed in a different sequence or can be added, merged, or left out altogether (for example, not all described acts or events are necessary for the practice of the algorithms). Moreover, in certain embodiments, acts or events can be performed concurrently, for example, through multi-threaded processing, interrupt processing, or multiple processors or processor cores or on other parallel architectures, rather than sequentially. In addition, different tasks or processes can be performed by different machines and/or computing systems that can function together.

The various illustrative logical blocks and modules described in connection with the embodiments disclosed herein can be implemented or performed by a machine, such as a processing unit or processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor can be a microprocessor, but in the alternative, the processor can be a controller, microcontroller, or state machine, combinations of the same, or the like. A processor can include electrical circuitry configured to process computer-executable instructions. In some embodiments, a processor includes an FPGA or other programmable device that performs logic operations without processing computer-executable instructions. A processor can also be implemented as a combination of computing devices, for example, a combination of a DSP and a microprocessor, one or more microprocessors, one or more microprocessors in conjunction with a DSP core, or any other such configuration. Although described herein primarily with respect to digital technology, a processor may also include primarily analog components. For example, some or all of the signal processing algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

Conditional language such as, among others, “can,” “could,” “might” or “may,” unless specifically stated otherwise, are understood within the context as used in general to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

Disjunctive language such as the phrase “at least one of X, Y, or Z,” unless specifically stated otherwise, is understood with the context as used in general to present that an item, term, etc., may be either X, Y, or Z, or any combination thereof (for example, X, Y, and/or Z). Thus, such disjunctive language is not generally intended to, and should not, imply that certain embodiments require at least one of X, at least one of Y, or at least one of Z to each be present. Any process descriptions, elements or blocks in the flow diagrams described herein

and/or depicted in the attached figures should be understood as potentially representing modules, segments, or portions of code which include one or more executable instructions for implementing specific logical functions or elements in the process. Alternate implementations are included within the scope of the embodiments described herein in which elements or functions may be deleted, executed out of order from that shown, or discussed, including substantially concurrently or in reverse order, depending on the functionality involved as would be understood by those skilled in the art.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations. For example, “a processor configured to carry out recitations A, B and C” can include a first processor configured to carry out recitation A working in conjunction with a second processor configured to carry out recitations B and C.

The technology as described herein may have also been described, at least in part, in terms of one or more embodiments, none of which is deemed exclusive to the other. Various configurations may omit, substitute, or add various procedures or components as appropriate. For instance, in alternative configurations, the methods may be performed in an order different from that described, or combined with other steps, or omitted altogether. This disclosure is further non-limiting and the examples and embodiments described herein does not limit the scope of the invention.

It should be emphasized that many variations and modifications may be made to the above-described embodiments, the elements of which are to be understood as being among other acceptable examples. All such modifications and variations are intended to be included herein within the scope of this disclosure.

1. A method of combining disparate 3d models of a common building object, the method comprising:
receiving a first plurality of images;
generating a first 3d model based on the first plurality of images, wherein the first 3d model is an interior model of the building object;
receiving a second plurality of images;
generating a second 3d model based on the second plurality of images, wherein the second 3d model is an exterior model of the building object; and
aligning, in a common 3d coordinate system, the first 3d model with the second 3d model,
wherein the first 3d model and the second 3d model comprise primitive-based models.

2.-4. (canceled)

5. The method of claim 1,
wherein the first plurality of images comprises an interior of the building object; and
wherein the second plurality of images comprises an exterior of the building object.

6.-10. (canceled)

11. The method of claim 1, further comprising generating the common 3d coordinate system by matching the first coordinate system with the second coordinate system.

12.-21. (canceled)

22. The method of claim 1, further comprising:
identifying a first plurality of sides of the first 3D model; and
identifying a second plurality of sides of the second 3D model,
wherein aligning the first 3D model with the second 3D model comprises aligning the first plurality of sides with the second plurality of sides in the common 3d coordinate system such that the first plurality of sides are within a threshold number of 3D pixels of the second plurality of sides.

23.-25. (canceled)

26. The method of claim 22, wherein the first plurality of sides and the second plurality of sides are planar surfaces, and wherein aligning the first 3D model with the second 3D model is based on surface normals of the first plurality of sides and the second plurality of sides.

27. (canceled)

28. The method of claim 26, wherein aligning the first 3D model with the second 3D model comprises aligning a first side of the first plurality of sides with a corresponding first side of the second plurality of sides such that a surface normal of the first side of the first plurality of sides is within a threshold number of degrees of a surface normal of the corresponding first side of the second plurality of sides.

29.-52. (canceled)

53. The method of claim 1, further comprising:
identifying a first plurality of elements of the first 3D model;
identifying a second plurality of elements of the second 3D model; and
correlating the first plurality of elements with the second plurality of elements,
wherein aligning the first 3D model with the second 3D model is based on the correlated plurality of elements.

54.-58. (canceled)

59. The method of claim 53, further comprising:
identifying a third plurality of elements, wherein the third plurality of elements comprises elements common to the first plurality of elements and the second plurality of elements;
wherein aligning the first 3D model with the second 3D model is based on the third plurality of elements.

60.-61. (canceled)

62. The method of claim 53, further comprising:
identifying an aspect of an element of the first plurality of elements;
identifying a corresponding aspect of a corresponding element of the second plurality of elements;
wherein aligning the first 3D model with the second 3D model comprises aligning the aspect of the element of the first plurality of elements with the corresponding aspect of the corresponding element of the second plurality of elements.

63.-64. (canceled)

65. The method of claim 1, further comprising:
identifying a first plurality of elements of the first plurality of images;
identifying a second plurality of elements of the second plurality of images; and
correlating the first plurality of elements with the second plurality of elements,
wherein aligning the first 3D model with the second 3D model is based on the correlated plurality of elements.

66.-86. (canceled)

87. The method of claim 1, further comprising:
matching an architectural element of the first 3D model with a corresponding architectural element of the second 3D model;
wherein aligning the first 3D model from the second 3D model is based on the matched architectural element.

88. The method of claim 1, further comprising:
matching an architectural element of the first plurality of images with a corresponding architectural element of the second plurality of images;
wherein aligning the first 3D model from the second 3D model is based on the matched architectural element.

89.-93. (canceled)

94. The method of claim 1, further comprising:
matching a non-architectural element of the first 3D model with a corresponding non-architectural element of the second 3D model;
wherein aligning the first 3D model from the second 3D model is based on the matched non-architectural element.

95. The method of claim 1, further comprising:
matching a non-architectural element of the first plurality of images with a corresponding non-architectural element of the second plurality of images;
wherein aligning the first 3D model from the second 3D model is based on the matched architectural element.

96.-100. (canceled)

101. The method of claim 1, wherein aligning the first 3D model with the second 3D model comprises scaling the first 3D model based on the second 3D model.

102.-105. (canceled)

106. The method of claim 1, wherein the first plurality of images are associated with a first plurality of camera poses, wherein the second plurality of images are associated with a second plurality of camera poses, and wherein aligning the first 3D model with the second 3D model is based on relative locations of the first plurality of camera poses and the second plurality of camera poses.

107.-119. (canceled)

120. The method of claim 1, wherein aligning the first 3D model with the second 3D model comprises:
reconstructing the first 3D model based on the second 3D model; and
reconstructing the second 3D model based on the first 3D model.

121. (canceled)

122. A non-transient computer-readable storage medium having instructions embodied thereon, the instructions being executable by one or more processors to perform a method for combining disparate 3d models of a common building object, the method comprising:
receiving a first plurality of images;
generating a first 3d model based on the first plurality of images, wherein the first 3d model is an interior model of the building object;
receiving a second plurality of images;
generating a second 3d model based on the second plurality of images, wherein the second 3d model is an exterior model of the building object; and
aligning, in a common 3d coordinate system, the first 3d model with the second 3d model;
wherein the first 3d model and the second 3d model comprise primitive-based models.

123.-242. (canceled)

243. A system configured for combining disparate 3d models of a common building object, the system comprising:
one or more hardware processors configured with machine-readable instructions to:
receiving a first plurality of images;
generating a first 3d model based on the first plurality of images, wherein the first 3d model is an interior model of the building object;
receiving a second plurality of images;
generating a second 3d model based on the second plurality of images, wherein the second 3d model is an exterior model of the building object; and
aligning, in a common 3d coordinate system, the first 3d model with the second 3d model;
wherein the first 3d model and the second 3d model comprise primitive-based models.

244.-363. (canceled)
